(19) United States
(12) Patent Application Publication
(10) Pub. No.: US 2025/0318352 A1
(43) Pub. Date: Oct. 9, 2025

(54) FUNCTIONALIZED AROMATIC PHOSPHONIC ACIDS FOR DISPLAY AND SOLAR CELL APPLICATIONS

(71) Applicants: Alan Sellinger, Lafayette, CO (US); Anastasia Alekseyevna Kuvayskaya, Golden, CO (US); Jinsong Huang, Chapel Hill, NC (US); Chengbin Fei, Chapel Hill, NC (US)

(72) Inventors: Alan Sellinger, Lafayette, CO (US); Anastasia Alekseyevna Kuvayskaya, Golden, CO (US); Jinsong Huang, Chapel Hill, NC (US); Chengbin Fei, Chapel Hill, NC (US)

(21) Appl. No.: 19/169,745

(22) Filed: Apr. 3, 2025

Related U.S. Application Data
(60) Provisional application No. 63/574,079, filed on Apr. 3, 2024.

(51) Int. Cl. H10K 30/86; C07F 9/572; H10K 30/40; H10K 50/15; H10K 85/10; H10K 85/50; H10K 85/60

(52) U.S. Cl. CPC H10K 30/86; C07F 9/5728; H10K 30/40; H10K 85/111; H10K 85/50; H10K 85/6572; H10K 50/15

(57) ABSTRACT

The present disclosure describes the synthesis, characterization, and purification of functionalized aromatic phosphonic acids (FAPAs) for use as hole extraction materials in perovskite solar cells and display devices. Embodiments of the present disclosure provide a method to prepare FAPAs with varying dipoles that can significantly improve the electronic properties of electrode materials used in displays and photovoltaic devices. The FAPA may be tuned for specific active layers. Aspects of the disclosure include phosphonic acid molecules that enhance bonding at the perovskite/substrate interface to create a strong hole extraction polymer retaining high efficiency and improving ultraviolet stability of perovskite solar cells by suppressing ion migration at the embedded interface.

### CROSS-REFERENCE TO RELATED APPLICATION

This application claims the benefit of priority under 35 U.S.C. § 119 (e) to U.S. provisional patent application 63/574,079, filed 3 Apr. 2024, the entirety of which is incorporated herein by reference.

### STATEMENT REGARDING FEDERALLY SPONSORED RESEARCH

This invention was made with government support under grant DE-EE0009520 awarded by the U.S. Department of Energy. The government has certain rights in the invention.

### FIELD

This disclosure relates generally to functionalized aromatic phosphonic acids for use as hole extraction materials in solar cell applications.

### BACKGROUND

Perovskite solar cells (PSCs) are becoming commercially viable due to their low cost, very high efficiency, improving durability, and scalability. However, known perovskite solar cells are less stable and less durable than solar cells made of other materials, such as silicon solar cells. For example, early perovskite solar cells degraded rapidly in outdoor settings and became non-functional within hours. Some newer perovskite devices have been demonstrated to have lifetimes of several months, but this is still not sufficient for outdoor commercial use. To be commercially viable for grid-level electricity production, a perovskite solar cell should have an operational life of at least 20, preferably 30 years.

With improved intrinsic durability and encapsulation, good light-soaking stability under accelerated conditions have been reported for some perovskite solar cells with the predicted solar resource/energy yield exceeding 90% probability (the “T₉₀” PV energy yield estimate) for over 10,000 hours not only for small perovskite solar cells, but also for perovskite minimodules. Several strategies have been reported to retain over 90% of the initial efficiencies of perovskite solar cells after the thermal-light stability at high temperature of 85° C. for less than 1,000 hours.

However, a huge gap exists between the indoor and outdoor durability testing results of perovskite solar cells. Almost all of the light-soaking stability tests of perovskite solar cells have been conducted using inorganic light emitting diodes (LEDs) as light sources which do not have a substantial ultraviolet (UV) component. There is no demonstration of outdoor stability showing perovskite solar cell minimodules with an area of greater than 25 cm² that still have an aperture efficiency above 15% after ten weeks of outdoor testing. Improved outdoor durability is needed for perovskite solar cells to be a commercially viable option as the next generation photovoltaic technology.

One way to protect perovskite solar cells that has been suggested is to completely or partially block UV light using a UV-filter layer, such as multiple encapsulation glass, or by using down-conversion luminescent materials. Unfortunately, using these materials to block UV light is not a good solution because these materials suffer from instability issues including wear over a period of years. Further, these materials increase the cost of perovskite solar cells and decrease energy yield.

Outdoor stability testing conditions are different from indoor light-soaking or maximum power point (MPP) tracking in several ways, including temperature fluctuation, insolation variance, and significant UV light intensity. These variances are particularly problematic during summer months and at lower latitudes. It is speculated that the indoor-outdoor durability gap of perovskite solar cells mainly comes from the lack of (or weak) UV light produced by most LED lamps used for indoor testing because perovskite devices are frequently reported to pass the IEC61215 thermal cycling test.

UV light has been reported to accelerate the degradation of perovskite solar cells, but there is no consensus on the mechanisms for this degradation. Photocatalytic effect was considered as the main reason for UV-induced perovskite degradation in n-i-p structured perovskite solar cells with TiO₂ and SnO₂ as electron transport layers. The UV light generated electrons in TiO₂ were reported to convert oxygen adsorbed on TiO₂ into hydroxyl radicals which oxidize I⁻ to I₂. As will be appreciated by one of skill in the art, in an n-i-p solar cell, the electron transporting layer is deposited first, followed by the active layer (organic or perovskite), and then by a hole transporting layer.

Another study suggested that UV light could directly activate oxygen vacancies and the cations in TiO₂ and SnO₂, prompting the accumulation of 13. In p-i-n structured devices, UV light was also reported to directly break-down the chemical bonds in the organic hole-transporting materials (HTM), such as poly[bis(4-phenyl)(2,4,6-trimethylphenyl)amine] (PTAA), and thus introduce charge-trapping defects. In a p-i-n solar cell, the hole transporting layer is deposited first followed by the active layer (organic or perovskite), then the electron transporting layer.

Because of these and other deficiencies, improvements in durability and stability of perovskite solar cells are needed.

### SUMMARY

One aspect of the present disclosure is a method to narrow the gap between indoor and outdoor durability of perovskite solar cells.

Another aspect is a perovskite solar cell with improved bonding of hole-transporting materials which stabilize the perovskites/indium tin oxide (ITO) interfaces. Testing indicated that the trap density of the perovskite/ITO interfaces in perovskite solar cells increased with the exposure under UV light, leading to the generation of more positively-charged iodine interstitials, which accelerates the cation migration and phase segregation at the buried perovskites/ITO interface. The improved bonding of hole-transporting materials in the perovskite solar cells stabilized the interface of the perovskite/ITO. The perovskite solar cell minimodules with the hole-transporting materials of embodiments of the present disclosure demonstrated record outdoor stability.

Another aspect of the present disclosure is a synthetic process to produce aromatic phosphonic acid molecules with tunable properties for application in organic semiconductor devices. Particularly, the aromatic phosphonic acid molecules are represented by Formula 1a, 1b, 1c, 1d, 1e, 1f, 1g, or 1h:

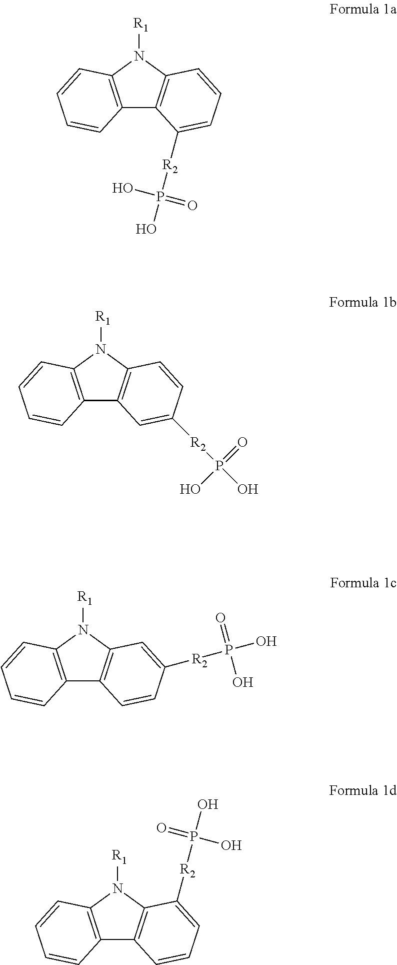

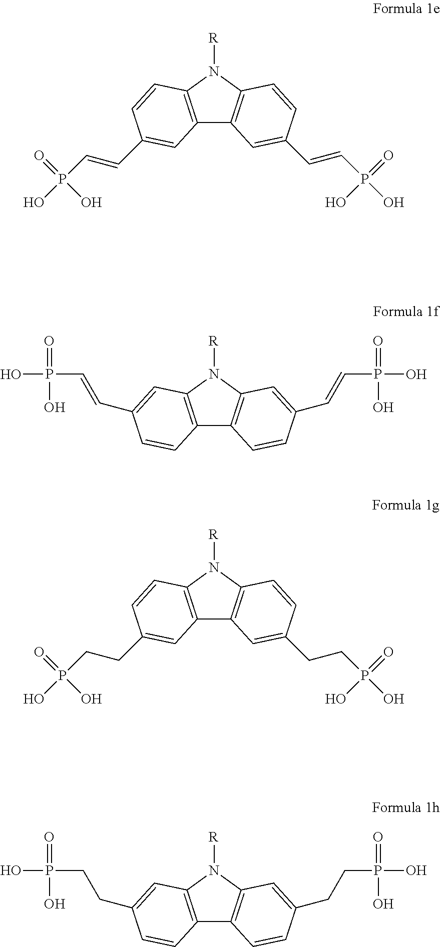

wherein R¹ or R is an alkyl group containing at least 1 and no more than 8 carbon atoms or a group of the form —CH₂CH₂ (OCH₂CH₂)ₙOCH₃, where n is an integer equal to at least 0 and no more than 5, and R² is ethyl or vinyl, or Formula 2:

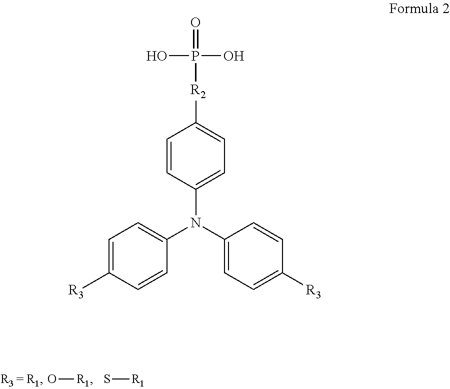

In certain embodiments, the phosphonic acid molecules comprise (2-(9-ethyl-9H-carbazol-3-yl)ethyl)phosphonic acid (EtCz3EPA), (E)-(2-(9-ethyl-9H-carbazol-3-yl)vinyl)phosphonic acid (EtCz3VPA), (E)-(2-(9-ethyl-carbazol-2-yl)vinyl)phosphonic acid (EtCz2VPA), (2-(9-ethyl-carbazol-2-yl)ethyl)phosphonic acid (EtCz2EPA), or a combination thereof.

Another aspect of the present disclosure is a chemical compound represented by one of the structural formulas

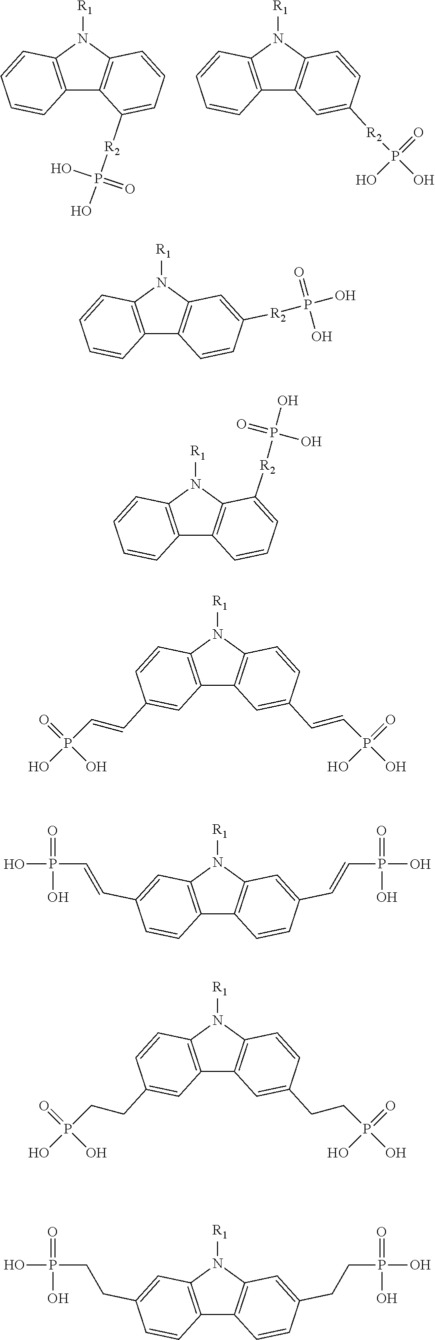

wherein R¹ or R is an alkyl group containing at least 1 and no more than 8 carbon atoms or a group of the form —CH₂CH₂ (OCH₂CH₂)ₙOCH₃, where n is an integer equal to at least 0 and no more than 5, and R² is ethyl or vinyl.

In certain embodiments, the chemical compound is (2-(9-ethyl-9H-carbazol-3-yl)ethyl)phosphonic acid (EtCz3EPA).

In certain embodiments, the chemical compound is (E)-(2-(9-ethyl-9H-carbazol-3-yl)vinyl)phosphonic acid (EtCz3VPA).

In certain embodiments, the phosphonic acid molecules are synthesized using 3-bromo-9-ethyl-9H-carbazole (3BrCz) and vinylphosphonic acid creating (E)-(2-(9-ethyl-9H-carbazol-3-yl)vinyl)phosphonic acid (EtCz3VPA). EtCz3VPA can be reduced to (2-(9-ethyl-9H-carbazol-3-yl)ethyl)phosphonic acid (EtCz3EPA).

In certain embodiments, the chemical compound is (2-(9-ethyl-carbazol-2-yl)ethyl)phosphonic acid (EtCz2EPA).

In certain embodiments, the chemical compound is (E)-(2-(9-ethyl-carbazol-2-yl)vinyl)phosphonic acid (EtCz2VPA).

In certain embodiments of using a carbazole starting material in synthesizing a functionalized carbazole, a nucleophile is present.

The nucleophile may, but need not, be potassium hydroxide.

In another aspect of the present disclosure, a perovskite solar cell comprises a layer comprising at least one linker molecule represented by one of the structural formulas

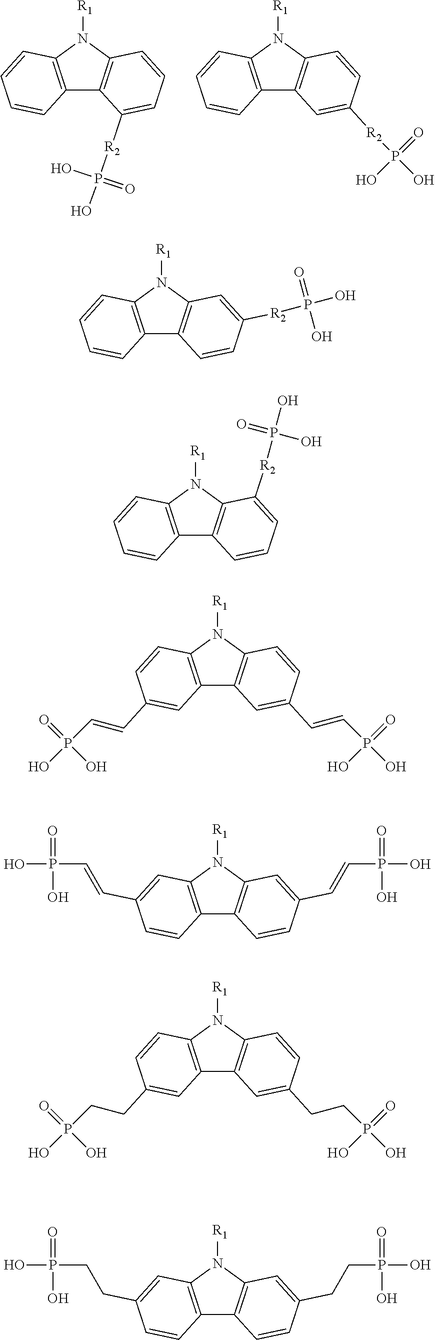

wherein R¹ or R is an alkyl group containing at least 1 and no more than 8 carbon atoms or a group of the form —CH₂CH₂ (OCH₂CH₂)ₙOCH₃, where n is an integer equal to at least 0 and no more than 5, and R² is ethyl or vinyl.

In certain embodiments, one or more of (2-(9-ethyl-9H-carbazol-3-yl)ethyl)phosphonic acid (EtCz3EPA) and (E)-(2-(9-ethyl-9H-carbazol-3-yl)vinyl)phosphonic acid (EtCz3VPA) are used as the linker molecule(s). Optionally, the linker molecule(s) replace the PTAA or form a linker/PTAA hybrid layer structure as a hole-transporting material.

Another aspect of the present disclosure is a method of making a perovskite solar cell containing a layer comprising a chemical compound represented by one of the structural formulas

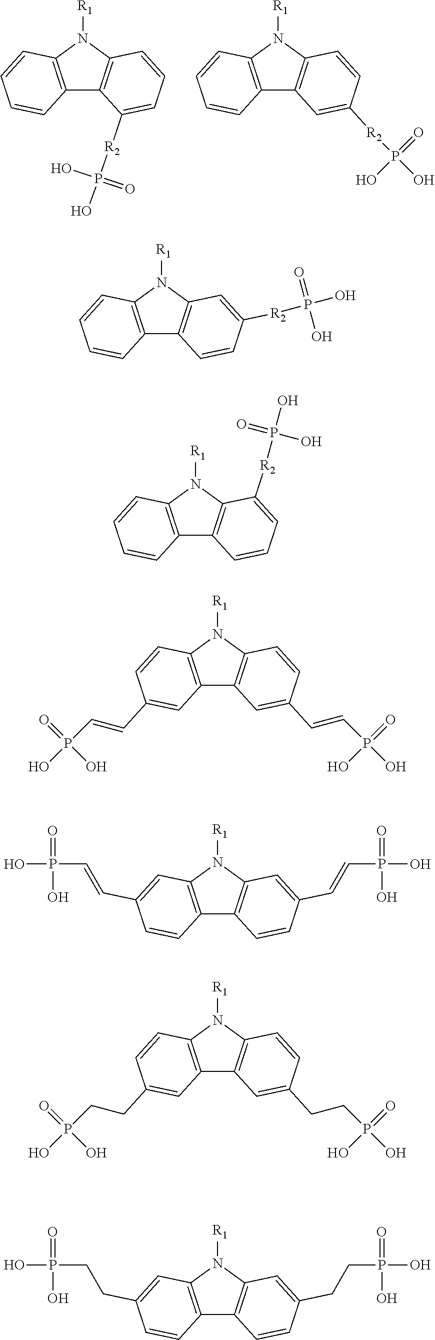

wherein R¹ or R is an alkyl group containing at least 1 and no more than 8 carbon atoms or a group of the form —CH₂CH₂ (OCH₂CH₂)ₙOCH₃, where n is an integer equal to at least 0 and no more than 5, and R² is ethyl or vinyl.

In certain embodiments, the method comprises preparation and coating of a poly[bis(4-phenyl)(2,4,6-trimethylphenyl)amine (PTAA) layer and a perovskite layer onto a transparent conducting oxide (TCO) substrate, e.g., an indium tin oxide glass substrate.

In certain embodiments, the method comprises the preparation and coating of a (2-(9-ethyl-9H-carbazol-3-yl)ethyl)phosphonic acid (EtCz3EPA) layer or an (E)-(2-(9-ethyl-9H-carbazol-3-yl)vinyl)phosphonic acid (EtCz3VPA) layer onto a CTO substrate.

In certain embodiments, one or more of the poly[bis(4-phenyl)(2,4,6-trimethylphenyl)amine layer, a perovskite layer, and the (2-(9-ethyl-9H-carbazol-3-yl)ethyl)phosphonic acid (EtCz3EPA) or (E)-(2-(9-ethyl-9H-carbazol-3-yl)vinyl)phosphonic acid (EtCz3VPA) layer is annealed, leaving a thin layer of chemical bonding to the CTO substrate, to form the perovskite solar cell.

In certain embodiments, the orientation of ligands from the TCO surface in a device is controlled. Possible orientations can comprise face-on or edge-on configurations.

Another aspect of the present disclosure is the carbazole backbone in molecules such as, but not limited to, EtCz2EPA or EtCz3EPA, having a face-on configuration to the substrate.

Another aspect of the present disclosure is the carbazole backbone in molecules such as, but not limited to, EtCz2VPA or EtCz3VPA, having an edge-on configuration to the substrate.

The Summary is neither intended nor should it be construed as being representative of the full extent and scope of the present disclosure. The present disclosure is set forth in various levels of detail in the Summary as well as in the attached drawings and the Detailed Description and no limitation as to the scope of the present disclosure is intended by either the inclusion or non-inclusion of elements, components, etc. in this Summary. Additional aspects of the present disclosure will become more clear from the Detailed Description, particularly when taken together with the drawings.

The phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

It is to be noted that the term “a” or “an” entity refers to one or more of that entity. As such, the terms “a” (or “an”), “one or more,” and “at least one” can be used interchangeably herein. It is also to be noted that the terms “comprising,” “including,” and “having” can be used interchangeably.

Unless otherwise indicated, all numbers expressing quantities, dimensions, conditions, ratios, ranges, and so forth used in the specification and claims are to be understood as being modified in all instances by the term “about” or “approximately.” When used with a number or a range, the terms “about” and “approximately” indicate the number or range may be “a little above” or “a little below” the endpoint with a degree of flexibility as would be generally recognized by those skilled in the art. Further, the terms “about” and “approximately” may include the exact endpoint, unless specifically stated otherwise. Accordingly, unless otherwise indicated, all numbers expressing quantities, dimensions, conditions, ratios, angles, ranges, and so forth used in the specification and claims may be increased or decreased by approximately 5% to achieve satisfactory results. Additionally, where the meaning of the terms “about” or “approximately” as used herein would not otherwise be apparent to one of ordinary skill in the art, the terms “about” and “approximately” should be interpreted as meaning within plus or minus 10% of the stated value.

Unless otherwise indicated, the term “substantially” indicates a different of from 0% to 5% of the stated value is acceptable.

All ranges described herein may be reduced to any sub-range or portion of the range, or to any value within the range. For example, the range “5 to 55” includes, but is not limited to, the sub-ranges “5 to 20” as well as “17 to 54.”

The use of “including,” “comprising,” or “having” and variations thereof herein is meant to encompass the items listed thereafter and equivalents thereof as well as additional items. Accordingly, the terms “including,” “comprising,” or “having” and variations thereof can be used interchangeably herein.

The embodiments and configurations described herein are neither complete nor exhaustive. As will be appreciated, other embodiments are possible utilizing, alone or in combination, one or more of the features set forth above or described in detail below.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIGS. 1A, 1B, and IC are schematic diagrams of interfacial contact of perovskite, the bifunctional molecular compounds of perovskite, and an ITO substrate, respectively.

FIG. 2 displays the synthetic route of EtCz3EPA.

FIGS. 3A, 3B, and 3C are J-V curves of PTAA-based small perovskite solar cell devices illuminated under LEP light (approximately 100 mW/cm², with approximately 3.5% UV inside, approximately 60° C., OC conditions) at the initial stage; a graph of the trap density of PTAA-based perovskite solar cells illuminated by LEP lamp for different times; and a graph of the trap density of PTAA-based perovskite solar cells illuminated by an LED lamp for different times, respectively.

FIG. 4 is an illustration for the transient reflection spectroscopy (TR) test of the perovskite films.

FIG. 5 is a graph displaying the indoor and outdoor light soaking stability of perovskite solar cells. The devices tested indoors were tested under an LED lamp (100 mW/cm², with <0.1% UV inside, 60±5° C., OC conditions). The perovskite solar cells tested outdoors were tested under sunlight and the average daytime temperatures during testing were approximately 20° C.

FIG. 6A is a graph of the TR decay of the perovskite films tested from the top side.

FIG. 6B is a graph of the TR decay of the perovskite films tested from the bottom side.

FIG. 7A is a before and after image of the two photoluminescence (PL) mapping of the perovskite solar cells before and after approximately 200 hours of light illumination under LEP light (approximately 100 mW/cm², with approximately 3.5% UV inside, 60±5° C., OC conditions). The scale bars are 10 μm.

FIG. 7B is a before and after image of the scanning electron microscopy (SEM) of the bottom perovskite layer before and after LEP light illumination. The scale bars are 5 μm.

FIG. 7C is a before and after image of the X-ray fluorescence (XRF) mapping of the Cs/I ratio of the bottom perovskite layer before and after light illumination. The scale bars are 5 μm.

FIGS. 8A, 8B, and 8C are images of the contact angles of a FAPbI₃ solution (1M, dissolved in 2-ME) on different HTM substrates: PTAA:BCP, EtCz3EPA, and EtCz3EPA/PTAA:BCP, respectively.

FIGS. 9A, 9B, and 9C are illustrations for the different hole-transporting materials on ITO substrates: PTAA:BCP, EtCz3EPA, and EtCz3EPA/PTAA:BCP, respectively.

FIGS. 10A, 10B, and 10C are atomic force microscope-infrared spectroscopy (AFM-IR) images of different hole transport materials on ITO substrates: PTAA:BCP, EtCz3EPA, and a hybrid hole-transporting material, respectively. The images were collected at the wavenumbers of 1028, 1012 and 1028 cm-1, respectively, corresponding to C—H bending in the —CH₃ groups. The scale bars in the images are 1 μm.

FIGS. 11A, 11B, and 11C are SEM images of the bottom morphology of a perovskite layer peeled from different ITO/HTM substrates before a 1,000 hour annealing process under 85° C. in the dark. FIG. 11A is a PTAA:BCP-based sample. FIG. 11B is a EtCz3EPA-based sample. FIG. 11C is a hybrid hole-transporting molecule-based sample. The scale bars in the images are 2 μm.

FIGS. 11D, 11E, and 11F are similar SEM images of the bottom morphology of perovskite layer peeled from different ITO/HTM substrates after the 1,000 hour annealing process under 85° C. in dark. FIG. 11D is a PTAA:BCP-based sample. FIG. 11E is a EtCz3EPA-based sample. FIG. 11F is a hybrid hole-transporting molecule-based sample. The scale bars in the images are 2 μm.

FIGS. 12A, 12B, and 12C are J-V curves of small perovskite solar cell devices (0.08 cm²) with different hole-transporting molecules: PTAA:BCP, EtCz3EPA and the hybrid HTM, respectively, and after approximately 50 hours of LEP light soaking.

FIGS. 13A, 13B, and 13C are graphs of the corresponding trap density of perovskite solar cells based on: PTAA:BCP, EtCz3EPA and a hybrid hole-transporting molecule, respectively, and illuminated by LEP light for approximately 50 hours.

FIGS. 14A and 14B are graphs of the light soaking stability of small area perovskite solar cell devices based on different hole-transporting molecule layers under the illumination of an LED lamp and an LEP lamp, respectively.

FIG. 14C is a graph displaying a damp heat test under 85° C. and 85% humidity of the small perovskite solar cell devices for 1,000 hours.

FIG. 14D is a thermal cycling test between-40 and 85° C. of the small perovskite solar cell devices for 200 cycles. For FIGS. 14A-14D, all the data for the small perovskite solar cell devices in the long-term stability test were collected from 20-30 devices for each group.

FIG. 15 is a graph of J-V curves of perovskite solar cell minimodules based on PTAA:BCP and hybrid hole-transporting molecules. The perovskite solar cell minimodules had an aperture area of approximately 17.88 cm² and PDMS antireflection layers were pre-soaked under an LED lamp for approximately 100 hours to achieve a high efficiency.

FIG. 16 is a photograph of the outdoor stability testing system for the perovskite solar cell modules.

FIGS. 17A and 17B are graphs of the daily output power and efficiency, respectively, of the perovskite solar cell minimodules.

FIG. 18 is a graph of the outdoor test of hybrid hole-transporting molecule-based perovskite solar cell minimodules. The perovskite solar cell minimodules were measured without a PDMS antireflection layer and stored in dark conditions for approximately 7 weeks before testing.

FIGS. 19A, 19B, and 19C are photographs of the perovskite solar cells (taken from the ITO/HTM side) before and after indoor and outdoor tests. The scale bars are 2 mm.

FIG. 20 is a schematic diagram of the degradation process of perovskite under light illumination with strong UV light.

FIG. 21 shows the detailed synthetic process of EtCz2VPA, EtCz2EPA, EtCz3VPA and EtCz3EPA.

FIG. 22 shows the height profiles of the self-assembled molecule (SAM) layers on silicon substrates after scribing as measured by atomic force microscopy.

FIG. 23 is a schematic of molecule stacking modes on a substrate.

FIG. 24 shows the current density-voltage (J-V) curves of the small devices with different SAM molecules as HTMs.

FIG. 25 shows J-V curves of the small devices with EtCz3EPA and EtCz3EPA/PTAA hybrid HTMs from different scanning directions.

FIG. 26 shows the trap density of the devices with different SAMs.

FIG. 27 shows light-soaking stability of the small devices with different SAMs as a hole transport layer (HTL). The data in FIGS. 25-28 were collected from 15-20 devices for each condition and the active area of the small devices was 0.08 cm². The devices were illuminated with a LEP lamp (100 mW/cm², with approximately 3.5% UV) and been heated up to approximately 60° C. by the lamp.

### DETAILED DESCRIPTION

Unless defined otherwise, all technical and scientific terms used herein have the same meaning as is commonly understood by one of ordinary skill in the art. All patents, applications, published applications, and other publications to which reference is made herein are incorporated by reference in their entirety. If there is a plurality of definitions for a term herein, the definition provided in the Summary prevails unless otherwise stated.

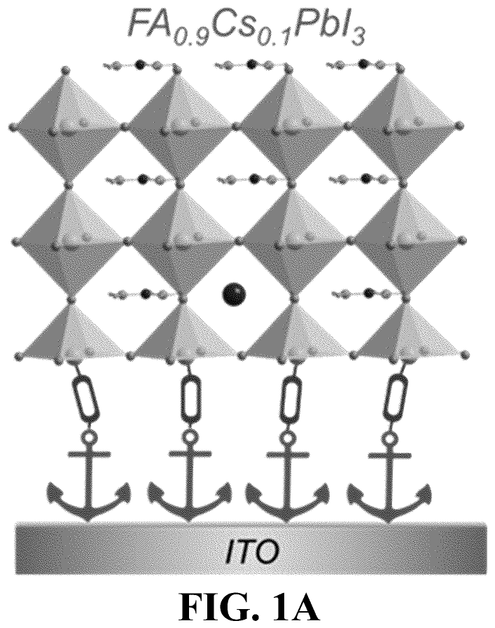

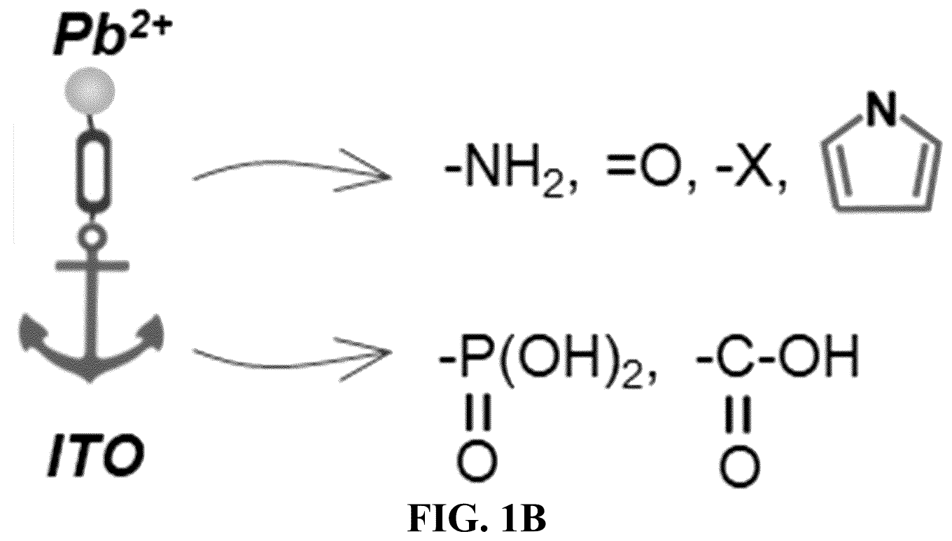

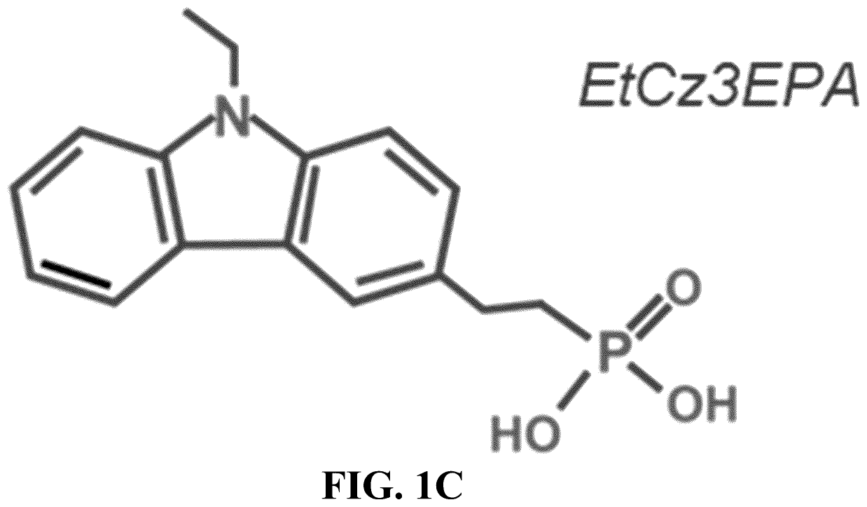

Enhancing the interaction of perovskites with transparent conducting oxide (TCO) substrates, e.g., indium tin oxide (ITO) substrates, and hole-transporting materials is needed to improve the UV stability (and thus outdoor stability) of perovskite solar cells. To this end, in some embodiments of the devices of the present disclosure, linker molecules are used to anchor the ITO at one end and the perovskite at the other end (FIGS. 1A-1C). A variety of compounds may be selected as linkers and employed to replace the PTAA or to form a linker/PTAA hybrid layer structure as the hole-transporting material. Particularly, the present disclosure is directed to one or more of functionalized and difunctionalized aromatic phosphonic acids, and more specifically chemical compounds represented by Formula 1a, 1b, 1c, 1d, 1e, 1f, 1g, or 1h:

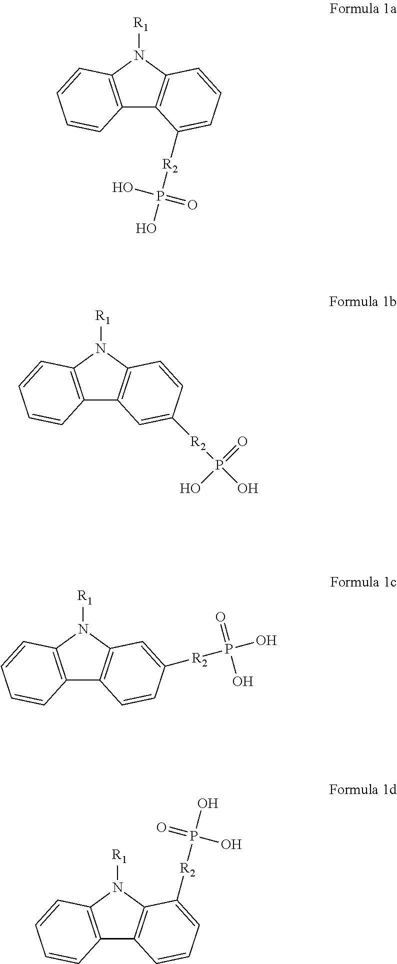

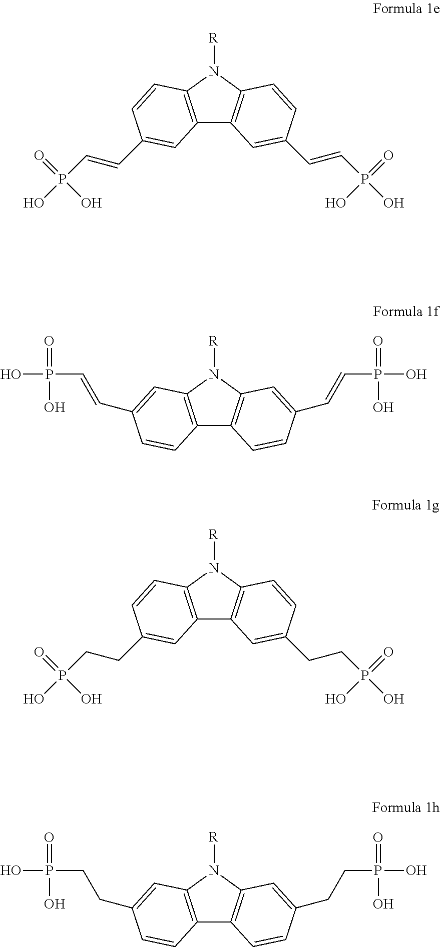

wherein R¹ or R is an alkyl group containing at least 1 and no more than 8 carbon atoms or a group of the form —CH₂CH₂ (OCH₂CH₂)ₙOCH₃, where n is an integer equal to at least 0 and no more than 5, and R² is ethyl or vinyl, or Formula 2:

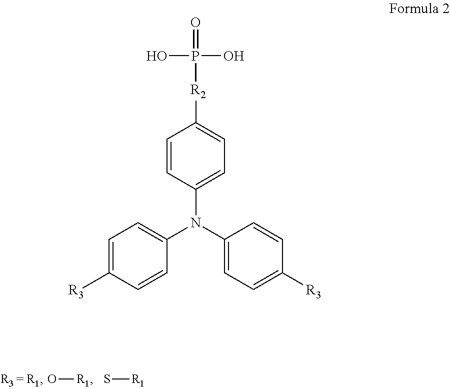

and use of these compounds as linker compounds/molecules in perovskite films and perovskite solar cells. In particular embodiments, (2-(9-ethyl-9H-carbazol-3-yl)ethyl)phosphonic acid (EtCz3EPA) and/or (E)-(2-(9-ethyl-9H-carbazol-3-yl)vinyl)phosphonic acid (EtCz3VPA) may be employed as linker compounds. Without wishing to be bound by any particular theory, the present inventors hypothesize that acid groups such as —COOH and —PO(OH)₂ in the linker molecules can be linked to the hydroxyl groups on an ITO substrate, while —NH—, ═O, halide (—X) and pyrrole groups in the linker molecules can interact with the Pb²⁺ in the perovskites.

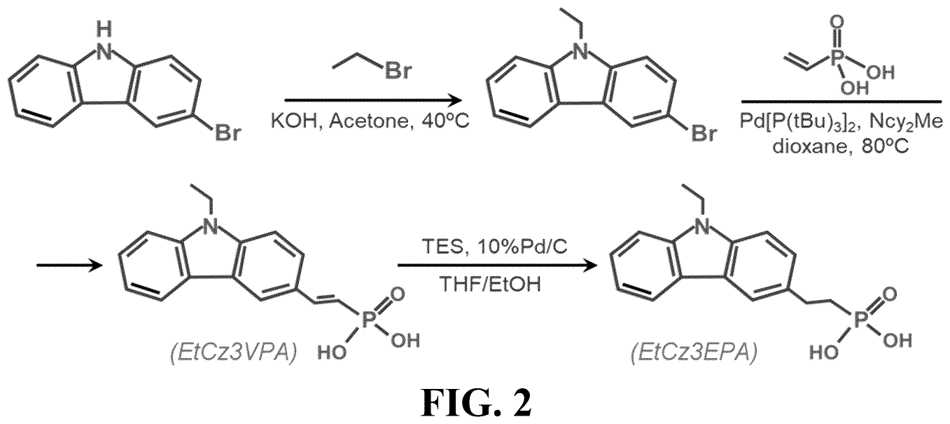

The functionalized aromatic phosphonic acids according to the present disclosure, e.g., EtCz3EPA and EtCz3VPA, have similar carbazole and phosphonate groups as the known linker compound (2-(9H-carbazol-9-yl)ethyl)phosphonic acid (2PACz), but differ in that, in the compounds according to the present disclosure, the linker with the phosphonic group is directly linked to the benzene rings rather than the nitrogen in the carbazole ring. The synthesis and material characteristics of these functionalized aromatic phosphonic acids are described further elsewhere throughout this disclosure, particularly in conjunction with FIG. 2. Perovskite solar cells fabricated with two of these compounds, EtCz3EPA and EtCz3VPA, exhibited higher efficiency and better stability under an LEP lamp. The carbazole in 2PACz can orient vertically to the substrate, making it difficult for the nitrogen in the pyrrole ring to interact with the Pb²⁺. By contrast, in the linker compounds according to the present disclosure, e.g., EtC23EPA and EtC23VPA, the carbazole group can rotate to an angle that is almost parallel to the ITO substrate, resulting in stronger coordination of the nitrogen with Pb²⁺. Therefore, the linker compounds disclosed herein, e.g., EtCz3EPA and EtCz3VPA, may be especially suitably chosen as the linker for perovskite solar cells in some embodiments of the present disclosure.

One advantage of the linker compounds, e.g., EtCz3EPA and EtCz3VPA, as disclosed herein is that reagents for their synthesis, which may in many embodiments include a bromocarbazole (e.g., 1-bromocarbazole, 2-bromocarbazole, 3-bromocarbazole, or 4-bromocarbazole) or a dibromocarbazole (e.g., 2,7-dibromocarbazole or 3,6-dibromocarbazole), dicyclohexylmethylamine, acetone, dioxane, triethyl silane, bromoethane (or chloroethane or iodoethane), and palladium catalysts (possibly such as palladium on carbon), can be easily obtained from commercial suppliers. Other materials for synthesis of the functionalized aromatic phosphonic acid linker compounds and/or construction of perovskite solar cells using such linker compounds may include 2-methoxyethanol, dimethyl sulfoxide, toluene, isopropyl alcohol, methanol, PbI₂, FAH2PO2, formamidinium iodide, formamidinium chloride, phenylammonium tetrafluoroborate, PTAA (which may typically have a number-average molecular weight of between about 7 kDa and about 10 kDa), CsI, ZnCl₂, carbohydrazide, bathocuproine, 4-pyrid-4-ylbenzoic acid, carprofen, 4-aminobenzylphosphonic acid, 1,1′-binaphthyl-2,2′-diyl hydrogen phosphate, and dibutyl phosphate.

A method of synthesis of EtCz3EPA according to at least one embodiment of the present disclosure is shown in FIG. 2. It will be understood that while a general order of the steps of the method is illustrated in FIG. 2, the method can include more or fewer steps, and the order of the steps can be performed differently than described herein. Further, although the steps of the method may be illustrated sequentially, many of the steps may in fact be performed in parallel or concurrently. As FIG. 2 illustrates, synthesis of EtCz3EPA first requires synthesis of 3-bromo-9-ethyl-9H-carbazole (3BECz) and subsequent conversion of 3BECz to E-(2-(9-ethyl-9H-carbazol-3-yl)vinyl)phosphonic acid (EtCz3VPA); the double bond of the vinyl moiety in the EtCz3VPA is then reduced to form the EtCz3EPA.

It is to be expressly understood that the procedure for synthesizing EtCz3EPA illustrated in FIG. 2 can easily be adapted to synthesize any chemical compound represented by one of the structural formulas

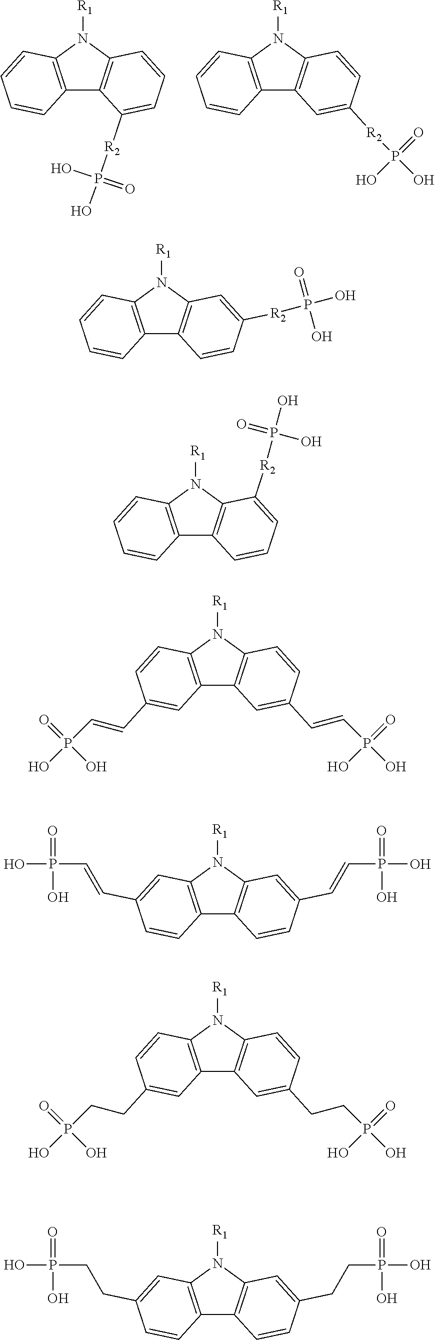

wherein R¹ or R is an alkyl group containing at least 1 and no more than 8 carbon atoms or a group of the form —CH₂CH₂ (OCH₂CH₂)ₙOCH₃, where n is an integer equal to at least 0 and no more than 5, and R² is ethyl, by simply replacing 3BECz with the appropriate 1-bromo-9-R¹-9H-carbazole, 1-bromo-9-R-9H-carbazole, 2-bromo-9-R¹-9H-carbazole, 2-bromo-9-R-9H-carbazole, 3-bromo-9-R¹-9H-carbazole, 3-bromo-9-R-9H-carbazole, 4-bromo-9-R¹-9H-carbazole, or 4-bromo-9-R-9H-carbazole; for example, where it is desired to synthesize (2-(9-propyl-9H-carbazol-3-yl)ethyl)phosphonic acid, 3-bromo-9-propyl-9H-carbazole may be used in place of 3BECz, mutatis mutandis, and the double bond in the vinyl moiety can then be reduced just as shown in FIG. 2. Any and all compounds represented by any of the structural formulas above wherein R² is ethyl, and methods for making such compounds by substituting the appropriate 1-bromo-9-R¹-9H-carbazole, 1-bromo-9-R-9H-carbazole, 2-bromo-9-R¹-9H-carbazole, 2-bromo-9-R-9H-carbazole, 3-bromo-9-R¹-9H-carbazole, 3-bromo-9-R-9H-carbazole, 4-bromo-9-R¹-9H-carbazole, or 4-bromo-9-R-9H-carbazole for 3BECz in the procedure illustrated in FIG. 2, are thus within the scope of the present disclosure. Similarly, it is to be expressly understood that the procedure for synthesizing EtCz3EPA illustrated in FIG. 2 can easily be adapted to synthesize any difunctionalized phosphonic acid compound (i.e., a compound having two phosphonic acid moieties, as shown in Formula 1e-1h) by simply replacing 3BECz with the appropriate 2,7-dibromo-9-R¹-9H-carbazole, 2,7-dibromo-9-R-9H-carbazole, 3,6-dibromo-9-R¹-9H-carbazole, or 3,6-dibromo-9-R-9H-carbazole; any and all such difunctionalized phosphonic acid compounds, and methods for making such compounds by substituting the appropriate 2,7-dibromo-9-R¹-9H-carbazole, 2,7-dibromo-9-R-9H-carbazole, 3,6-dibromo-9-R¹-9H-carbazole, or 3,6-dibromo-9-R-9H-carbazole for 3BECz in the procedure illustrated in FIG. 2, are thus within the scope of the present disclosure.

A method of synthesis of 3-bromo-9-ethyl-9H-carbazole (3BECz) according to embodiments of the present disclosure is described in the following paragraphs. It will be understood that while a general order of the steps of the method is described, the method can include more or fewer steps, and the order of the steps can be performed differently than described herein. Further, although the steps of the method may be described sequentially, many of the operations may in fact be performed in parallel or concurrently. It is to be expressly understood that the procedure described below for synthesizing 3BECz can easily be adapted to synthesize any bromo-9-R¹-9H-carbazole, bromo-9-R-9H-carbazole, dibromo-9-R¹-9H-carbazole, or dibromo-9-R-9H-carbazole wherein R¹, or R, is an alkyl group containing at least 1 and no more than 8 carbon atoms or a group of the form —CH₂CH₂ (OCH₂CH₂)ₙOCH₃, where n is an integer equal to at least 0 and no more than 5, by simply replacing the described bromoethane (or other haloethane, e.g., chloroethane or iodoethane) with the appropriate halogenated organic compound; for example, where it is desired to synthesize 3-bromo-9-propyl-9H-carbazole, bromopropane (or chloropropane, or iodopropane) may be used in place of bromoethane, mutatis mutandis. Equally, the bromine atom or atoms of the carbazole may be any other halogen atom or a triflate group, mutatis mutandis, i.e., the resulting carbazole compound may be 3-chloro-9-R¹-9H-carbazole, 3-chloro-9-R-9H-carbazole, 3-iodo-9-R¹-9H-carbazole, 3-iodo-9-R-9H-carbazole, etc., by substituting the appropriate starting halocarbazole, dihalocarbazole or (trifluoromethylsulfonyl)carbazole for the described 3-bromocarbazole. Any and all compounds of the form 1-R⁴-9-R¹-9H-carbazole, 2-R⁴-9-R¹-9H-carbazole, 3-R⁴-9-R¹-9H-carbazole, 4-R⁴-9-R¹-9H-carbazole, 2-R⁴-7-R⁵-9-R¹-9H-carbazole, 3-R⁴-6-R⁵-9-R¹-9H-carbazole, 1-R⁴-9-R-9H-carbazole, 2-R⁴-9-R-9H-carbazole, 3-R⁴-9-R-9H-carbazole, 4-R⁴-9-R-9H-carbazole, 2-R⁴-7-R⁵-9-R-9H-carbazole, or 3-R⁴-6-R⁵-9-R-9H-carbazole wherein R¹ or R is an alkyl group containing at least 1 and no more than 8 carbon atoms or a group of the form —CH₂CH₂ (OCH₂CH₂)ₙOCH₃, where n is an integer equal to at least 0 and no more than 5, and each of R⁴ and R⁵ is a halogen atom or a triflate group, and methods for making such compounds by substituting the appropriate halogenated organic compound for bromoethane (or other haloethane) and/or the appropriate halocarbazole, dihalocarbazole, or (trifluoromethylsulfonyl)carbazole for 3-bromocarbazole, are thus within the scope of the present disclosure.

A multi neck round-bottom flask with a stirring mechanism (such as a stir bar) is dried. In some embodiments, the flask may be dried in an oven. The flask may be of any appropriate volume. Optionally, the flask may have a volume of about 1 L.

The flask is fitted with an air condenser and charged with KOH (approximately 6.83 g, 0.122 mol) and 3-bromocarbazole (approximately 10.1 g, 0.0406 mol), followed by the vacuum and N₂ refill cycles. In some embodiments, the vacuum and refill cycles are repeated one or more times, and optionally these operations are repeated three or more times.

Acetone is gently bubbled with N₂ for approximately 20 minutes and added to the flask by a suitable method. In some embodiments, the acetone may be added by syringe with stirring.

Bromoethane (approximately 8.85 g, 0.0812 mol) may be added to the reaction mixture. Optionally, the bromoethane may be added dropwise via syringe.

The reaction is heated to approximately 40° C. for approximately 2 hours.

In some embodiments, the progress may be monitored with thin layer chromatography (ethyl acetate (EtOAc)/hexanes approximately 1:4).

Upon completion, the reaction mixture is cooled to room temperature (R.T.), for example 59° to 77° F. (15° to 25° C.).

The acetone is removed. Optionally, the acetone removal may be under vacuo.

Crude is dissolved in EtOAc and washed with 5% HCl. Optionally, the dissolving and washing may be repeated one or more times. In some embodiments, the dissolving and washing is repeated at least three times.

The organic phase is dried over MgSO₄ and filtered.

The organic phase which was obtained is condensed to a few milliliters. In some embodiments, the condensing is performed by a rotary evaporator.

The product is purified. In some embodiments, the purification is performed by flash column chromatography (EtOAc/hexanes approximately 1:4).

The purity of the product may subsequently be verified by any suitable means known to those of skill in the art. Optionally, the purity may be verified with GCMS and/or NMR.

The product is dried for a predetermined period of time between approximately 42° C. and 48° C., or approximately 45° C., under vacuum. In some embodiments, at this point the product may appear as off-white crystals. Optionally, the predetermined period of time is between 2-14 hours, although other periods of time are contemplated.

A method of synthesis of E-(2-(9-ethyl-9H-carbazol-3-yl)vinyl)phosphonic acid (EtCz3VPA) according to some embodiments of the present disclosure is described in the following paragraphs. It will be understood that while a general order of the steps of the method is described, the method can include more or fewer steps, and the order of the steps can be performed differently than described herein. Further, although the steps of the method may be described sequentially, many of the steps may in fact be performed in parallel or concurrently. It is to be expressly understood that the procedure for synthesizing EtCz3VPA described below can easily be adapted to synthesize any chemical compound represented by any of the structural formulas

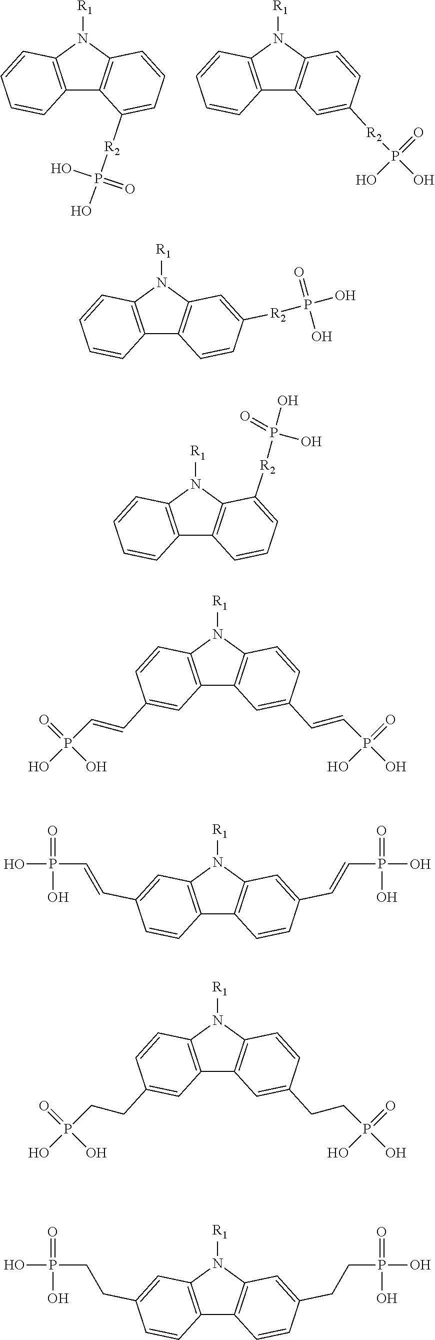

wherein R¹ or R is an alkyl group containing at least 1 and no more than 8 carbon atoms or a group of the form —CH₂CH₂ (OCH₂CH₂)ₙOCH₃, where n is an integer equal to at least 0 and no more than 5, and R² is vinyl, by simply replacing 3BECz with the appropriate 1-bromo-9-R¹-9H-carbazole, 1-bromo-9-R-9H-carbazole, 2-bromo-9-R¹-9H-carbazole, 2-bromo-9-R-9H-carbazole, 3-bromo-9-R¹-9H-carbazole, 3-bromo-9-R-9H-carbazole, 4-bromo-9-R¹-9H-carbazole, or 4-bromo-9-R-9H-carbazole; for example, where it is desired to synthesize (2-(9-propyl-9H-carbazol-3-yl)vinyl)phosphonic acid, 3-bromo-9-propyl-9H-carbazole may be used in place of 3BECz, mutatis mutandis. Any and all compounds represented by any of the structural formulas above wherein R² is vinyl, and methods for making such compounds by substituting the appropriate 2-bromo-9-R¹-9H-carbazole, 2-bromo-9-R-9H-carbazole, 3-bromo-9-R¹-9H-carbazole, or 3-bromo-9-R-9H-carbazole for 3BECz in the procedure described below, are thus within the scope of the present disclosure. Similarly, it is to be expressly understood that the procedure for synthesizing EtCz3VPA described in the following paragraphs can easily be adapted to synthesize any difunctionalized phosphonic acid compound (i.e., a compound having two phosphonic acid moieties, as shown in Formula 1e-1h) by simply replacing 3BECz with the appropriate 2,7-dibromo-9-R¹-9H-carbazole, 2,7-dibromo-9-R-9H-carbazole, 3,6-dibromo-9-R¹-9H-carbazole, or 3,6-dibromo-9-R-9H-carbazole; any and all such difunctionalized phosphonic acid compounds, and methods for making such compounds by substituting the appropriate 2,7-dibromo-9-R¹-9H-carbazole, 2,7-dibromo-9-R-9H-carbazole, 3,6-dibromo-9-R¹-9H-carbazole, or 3,6-dibromo-9-R-9H-carbazole for 3BECz in the procedure described in the following paragraphs, are thus within the scope of the present disclosure.

A Schlenk flask of an appropriate volume and with a stirring mechanism is dried. In some embodiments, the Schlenk flask has a volume of approximately 500 mL. The stirring mechanism may be a stir bar, but other suitable stirring mechanisms known to those of skill in the art may be used. The drying may be performed by any suitable method, such as by oven drying.

The Schlenk flask is charged with 3BECz (approximately 7.02 g, 0.0222 mol) and bis(tri-tert-butylphosphine) palladium (0) (approximately 0.326 g, 0.640 mmol), followed by vacuum and a N₂ refill cycle. Vacuum and refill operations may be performed one or more times. In some embodiments, the vacuum and refill operations are performed three or more times.

Vinyl phosphonic acid (VPA) (approximately 3.32 g, 0.0266 mol) is dissolved in approximately 25 mL of anhydrous dioxane and bubbled with N₂ for approximately 20 minutes.

Approximately 325 mL of anhydrous dioxane and solution of VPA is added to the Schenk flask. Optionally, one or more of the anhydrous dioxane and solution of VPA are added via syringe with stirring.

N,N-Dicyclohexylmethylamine (10.8 mL, 0.0666 mol) is added to the reaction mixture by any appropriate means. In some embodiments, the N,N-Dicyclohexylmethylamine is added dropwise via syringe.

The reaction is heated to approximately 80° C. for a predetermined period of time. In at least one embodiment, the predetermined heating is conducted between approximately 15 hours and 25 hours, or approximately 20 hours.

Optionally, the progress is monitored with thin layer chromatography (EtOAc/hexanes approximately 1:4).

Upon completion, the reaction mixture is cooled to a predetermined temperature. In at least one embodiment, the predetermined temperature is between approximately 59° to 77° F. (15° to 25° C.).

The product is extracted with EtOAc and washed with 5% HCl. Optionally, washing may be repeated two or more times. In at least one embodiment, the washing is repeated three times.

The organic phase is dried over MgSO₄ and filtered.

The obtained organic phase is condensed to a few mL. In some embodiments, the condensing is performed by a rotary evaporator.

The product is precipitated into DCM.

The filtered precipitate is dried for a predetermined period of time between approximately 42° C. and 48° C., or approximately 45° C. under vacuum. In some embodiments, at this point the filtered precipitated product may appear as faint olive-green fibers. Optionally, the predetermined period of time is between 2 to 14 hours, although other periods of time are contemplated.

A method of synthesis of EtCz3EPA according to embodiments of the present disclosure is described in the following paragraphs. It will be understood that while a general order of the steps of the method is described, the method can include more or fewer steps, and the order of the steps can be performed differently than described herein. Further, although the steps of the method may be described sequentially, many of the steps may in fact be performed in parallel or concurrently.

It is to be expressly understood that the procedure for synthesizing EtCz3EPA described below can easily be adapted to synthesize any chemical compound represented by any of the structural formulas

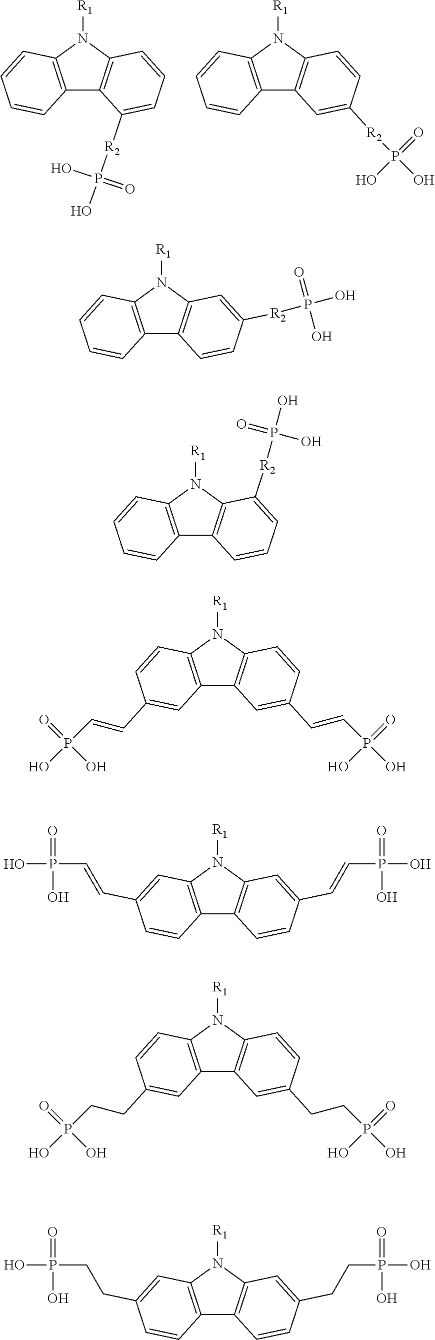

wherein R¹ or R is an alkyl group containing at least 1 and no more than 8 carbon atoms or a group of the form —CH₂CH₂ (OCH₂CH₂)ₙOCH₃, where n is an integer equal to at least 0 and no more than 5, and R² is ethyl, by simply replacing 3BECz with the appropriate 1-bromo-9-R¹-9H-carbazole, 1-bromo-9-R-9H-carbazole, 2-bromo-9-R¹-9H-carbazole, 2-bromo-9-R-9H-carbazole, 3-bromo-9-R¹-9H-carbazole, 3-bromo-9-R-9H-carbazole, 4-bromo-9-R¹-9H-carbazole, or 4-bromo-9-R-9H-carbazole; for example, where it is desired to synthesize (2-(9-propyl-9H-carbazol-3-yl)ethyl)phosphonic acid, 3-bromo-9-propyl-9H-carbazole may be used in place of 3BECz, mutatis mutandis, and the double bond in the vinyl moiety can then be reduced as described below. Any and all compounds represented by any of the structural formulas above wherein R² is ethyl, and methods for making such compounds by substituting the appropriate 1-bromo-9-R¹-9H-carbazole, 1-bromo-9-R-9H-carbazole, 2-bromo-9-R¹-9H-carbazole, 2-bromo-9-R-9H-carbazole, 3-bromo-9-R¹-9H-carbazole, 3-bromo-9-R-9H-carbazole, 4-bromo-9-R¹-9H-carbazole, or 4-bromo-9-R-9H-carbazole for 3BECz in the procedure described below, are thus within the scope of the present disclosure. Similarly, it is to be expressly understood that the procedure for synthesizing EtCz3EPA described in the following paragraphs can easily be adapted to synthesize any difunctionalized phosphonic acid compound (i.e., a compound having two phosphonic acid moieties, as shown in Formula 1e-1h) by simply replacing 3BECz with the appropriate 2,7-dibromo-9-R¹-9H-carbazole, 3,6-dibromo-9-R¹-9H-carbazole, 2,7-dibromo-9-R-9H-carbazole, or 3,6-dibromo-9-R-9H-carbazole; any and all such difunctionalized phosphonic acid compounds, and methods for making such compounds by substituting the appropriate 2,7-dibromo-9-R¹-9H-carbazole, 3,6-dibromo-9-R¹-9H-carbazole, 2,7-dibromo-9-R-9H-carbazole, or 3,6-dibromo-9-R-9H-carbazole for 3BECz in the procedure described in the following paragraphs, are thus within the scope of the present disclosure.

A Schlenk flask of an appropriate volume and with a stirring mechanism is dried. The stirring mechanism may be a stir bar, but other suitable stirring mechanisms known to those of skill in the art may be used. The drying may be performed by any suitable method, such as by oven drying.

The Schlenk flask is charged with 10% Pd/C (approximately 0.063 g, 0.030 mmol) and EtCz3VPA (approximately 0.390 g, 0.119 mmol), followed by vacuum and N₂ refill cycles. In some embodiments, one or more of the vacuum, and refill operations may be performed two or more times. In at least one embodiment, one or more of the vacuum, and refill operations is performed three or more times.

Approximately 15 mL of anhydrous dioxane and approximately 1.2 mL of ethanol is added to the Schlenk flask by a suitable method. In at least one embodiment, the anhydrous dioxane and/or the ethanol are added by syringe with stirring.

The solution is stirred at room temperature (between approximately 59° to 77° F. (15° to 25° C.)) until the solids are dissolved.

After the stirring, the solution is cooled to a predetermined temperature. In one or more embodiments, the cooling may be performed by placing the solution on ice.

During the cooling, triethyl silane is added to the reaction mixture by any appropriate method known to those of skill in the art. In at least one embodiment, the triethyl silane is added dropwise via syringe. In some embodiments approximately 1.11 g, 9.52 mmol of the triethyl silane is added.

The solution is also stirred a first time during the cooling for a predetermined period of time. In some embodiments, the predetermined period of time for the first stirring is between approximately 11 minutes and 19 minutes, or approximately 15 minutes.

Thereafter, the solution is stirred a second time until bubbling has stopped. The predetermined period of time for the second stirring may be up to approximately 30 minutes, or up to approximately 45 minutes. In at least one embodiment, the second stirring is performed at room temperature (approximately 59° to 77° F. (15° to 25° C.)).

The reaction mixture is heated to approximately 35° C.

The reaction mixture is stirred a third time for a third predetermined period of time. In one or more embodiments, the third predetermined period of time is between approximately 2.5 and 3.5 hours, or approximately 3 hours.

Optionally, the reaction progress is monitored by an appropriate means. In some embodiments, the reaction progress is monitored with 31P NMR. Small aliquots are dissolved in a small amount of ethyl acetate and run through a syringe filter, the solvent is removed under vacuo, and crude is dissolved in DMSO-d6.

Upon completion, the reaction mixture is cooled to a predetermined temperature. In some embodiments, the predetermined temperature is between approximately 59° to 77° F. (15° to 25° C.).

The solution is run through a short silane plug.

The collected solution is condensed under vacuo.

The product is extracted and washed with 5% HCl. In some embodiments, the extraction is performed with EtOAc. In at least one embodiment, one or more of the extraction and the washing are repeated two or more times, or at least three times.

The organic phase is dried over MgSO₄ and filtered.

The obtained organic phase is condensed to a few mL. In at least one embodiment, the condensing is conducted with a rotary evaporator.

The product is precipitated into DCM.

The filtered precipitate is dried for a predetermined period of time at a predetermined temperature under vacuum. In some embodiments, the predetermined period of time is between approximately 2-14 hours. The predetermined temperature may be between approximately 42° C. and 48° C., or approximately 45° C.

A method of synthesis of (2-(9-ethyl-carbazol-2-yl)ethyl)phosphonic acid (EtCz2EPA) according to embodiments of the present disclosure is the same as (or similar to) those described above for (2-(9-ethyl-carbazol-3-yl)ethyl)phosphonic acid (EtCz3EPA). Accordingly, the steps of the method are not repeated here. It will be understood that while a general order of the steps of the method is described above with respect to EtCz3EPA, the method can include more or fewer steps, and the order of the steps can be performed differently than described herein. Further, although the steps of the method may be described sequentially, many of the operations may in fact be performed in parallel or concurrently.

A method of synthesis of (E)-(2-(9-ethyl-carbazol-2-yl)vinyl)phosphonic acid (EtCz2VPA) according to embodiments of the present disclosure is the same as (or similar to) those described above for (E)-(2-(9-ethyl-carbazol-3-yl)vinyl)phosphonic acid (EtCz3VPA). Accordingly, the steps of the method are not repeated here. It will be understood that while a general order of the steps of the method is described above with respect to EtCz3VPA, the method can include more or fewer steps, and the order of the steps can be performed differently than described herein. Further, although the steps of the method may be described sequentially, many of the operations may in fact be performed in parallel or concurrently.

Perovskite solar cells according to embodiments of the present disclosure may be produced by the following method. It will be understood that while a general order of the steps of the method is described, the method can include more or fewer steps, and the order of the steps can be performed differently than described herein. Further, although the steps of the method may be described sequentially, many of the steps may in fact be performed in parallel or concurrently.

ITO glass substrates with resistance of approximately 15 Ωsq⁻¹ are obtained. The ITO glass substrates are pre-patterned and cleaned. In some embodiments, the ITO glass substrates are cleaned by acetone in an ultrasonic machine.

The ITO glass substrates are pre-treated by UV-ozone for between about 10 and 20 minutes, or approximately 15 minutes.

A PTAA layer, a bilateral molecule layer and a perovskite layer are prepared by any suitable method known to those of skill in the art. In some embodiments, one or more of the layers is prepared by blade-coating at ambient conditions (approximately 20° C., 30-50% RH) inside a fume hood. In some embodiments, the PTAA layer is pure. Alternatively, in other embodiments, the PTAA layer is a 2% wt. BCP doped PTAA (PTAA:BCP) layer.

Optionally, for the preparation of the PTAA or PTAA:BCP layer, the solution (2.2 mg mL⁻¹, in TL) is blade-coated onto the ITO glass substrates at a speed of approximately 20 mm s⁻¹ and a coating gap of approximately 150 μm.

In some embodiments, when preparing the PTAA or PTAA:BCP layer on an ITO glass substrate of approximately 15.0 cm×12.0 cm, 68-72 μL of the solution is injected. For the preparation of EtCz3EPA or other bilateral molecule layer, the EtCz3EPA (or other bilateral molecule layer) is dissolved in methanol with a concentration of approximately 1 mg/mL, then blade-coated onto the ITO substrate glass with the same blading parameters of the PTAA layer.

The EtCz3EPA or other bilateral molecule coated substrate is then annealed at approximately 150° C. for 3-5 minutes and washed to remove the residue molecule, leaving only a thin layer with very strong chemical bonding to the ITO glass substrate. In some embodiments, the washing comprises the use of methanol.

For the preparation of the hybrid hole-transporting material layer, EtCz3EPA/PTAA:BCP, a PTAA:BCP layer is coated on the above EtCz3EPA layer. In some embodiments, this layer is applied with the same blading parameters as described above.

1 M FA_{0.9}Cs_{0.1}PbI₃ may be prepared by directly mixing FAPbI₃ (in 2-ME), CsPbI₃ (in DMSO) and other additives (in 2-ME) and diluting with 2-ME solvent prior to blade coating. Approximately 0.23% v/v FAH₂PO₂, approximately 2.3 mg mL⁻¹ FACl, approximately 0.25 mg mL⁻¹ PEABF₄, approximately 0.57 mg mL⁻¹ CsI, approximately 0.74 mg mL⁻¹ ZnCl₂ and approximately 0.18 mg mL⁻¹ CBH are added into the precursor solutions as additives. The function of the additives FAH₂PO₂, FACl, PEABF₄, CsI, ZnCl₂ and CBH is described in Fei, C. et al., “Lead-chelating hole-transport layers for efficient and stable perovskite minimodules,” Science 380, 823-829, doi: 10.1126/science.ade9463 (2023), which is incorporated herein by reference in its entirety. Finally, the precursor solution is blade-coated onto the hole-transporting material-covered ITO glass substrates with a gap of approximately 350 μm at a coating speed of approximately 20 mm s⁻¹.

A perovskite solar cell minimodule according to embodiments of the present disclosure may be fabricated with an ITO glass substrate of approximately 15.0 cm×12.0 cm, by injecting approximately 125-130 μL of perovskite solution. The wet perovskite films are then transferred onto a heating mechanism, in some embodiments this heating mechanism is a hot plate, and annealed at approximately 150° C. for approximately 4 minutes in air. The thickness of the final perovskite films is between approximately 750 and 950 nm, or between approximately 800 and 900 nm.

The perovskite solar cells are completed by evaporating C₆₀ (approximately 30 nm, approximately 0.15 Å s⁻¹), BCP (approximately 6 nm, approximately 0.1 Å s⁻¹), and approximately 150 nm copper (approximately 1 Å s⁻¹). In some embodiments, the evaporating is performed by thermal evaporation.

The active area of the perovskite solar cells according to embodiments of the present disclosure is approximately 0.08 cm² (approximately 0.4 cm by 0.2 cm determined by a metal shadow mask). However, the perovskite solar cells of the present disclosure are not limited to only these dimensions. Optionally, the perovskite solar cells may have larger (or smaller) surface areas and dimensions.

In other embodiments, a perovskite solar cell according to the present disclosure may optionally be fabricated on pre-patterned large ITO glass substrates with P1 width (as described in Xuezeng Dai et al., “Pathways to high efficiency perovskite monolithic solar modules,” 1(1) PRX Energy 013004 (May 2022)) (which is incorporated herein by reference in its entirety) of approximately 50 μm followed by substantially the same method of making perovskite solar cells described above.

In some embodiments, the laser scribing may be performed with a Keyence laser marker (MD-U1000C, 355 nm). Optionally, in some embodiments, the laser scribing is performed two or more times.

Optionally, the width of each subcell of the perovskite solar cell is between approximately 6 mm and 7 mm, or 6.5 mm.

In some embodiments, the final P2 and P3 widths are approximately 110 and approximately 75 μm, respectively. However, the perovskite solar cells of the present disclosure are not limited to these dimensions.

In at least one embodiment of the present disclosure, the total width of the non-working area of a perovskite solar cell is approximately 380 μm, giving a geometrical fill factor (GFF) of approximately 94.1%.

Optionally, the perovskite solar cells of some embodiments of the present disclosure may be formed without an antireflection layer at the front side. Alternatively, in other embodiments, an antireflection layer is formed at the front side of the perovskite solar cells.

Despite the structural similarities between (2-(9-ethyl-9H-carbazol-3-yl)ethyl)phosphonic acid (EtCz3EPA) and (2-(9-ethyl-9H-carbazol-3-yl)vinyl)phosphonic acid (EtCz3VPA) on the one hand and previously reported phosphonic acid-functionalized carbazoles on the other hand, there are significant differences among the compounds. One main difference is the optimized synthetic approach, which does not require highly corrosive and toxic reagents, thus allowing the opportunity to expand the scope of the reaction. For example, using an approach as described in PCT Application Publication 2019/207029 to Magomedov et al. (which is incorporated by reference herein in its entirety) is likely not as functional as it has two reaction steps that are unlikely to transition well to large scale manufacturing. The first is the use of triethylphosphite (P(OEt)₃) to react with a bromoalkene at high temperatures (above 100° C.). Triethylphosphite is toxic and has a pungent smell that is difficult to contain. Second, the Kaunas approach uses bromotrimethylsilane, which is dangerous and very corrosive, as it reacts with water in the atmosphere to produce highly corrosive hydrobromic acid (HBr). Furthermore, these corrosive approaches limit other functional groups on the resultant phosphonic acids, such as nitriles, esters, amines, sulfides, etc., that could be beneficial as moieties to interact with the perovskite layer. The approach to preparing the phosphonic acids disclosed herein utilizes relatively mild Heck coupling conditions that allow aromatic vinyl phosphonic acids (CzPA) with a variety of functional groups to be obtained. The disclosed embodiments also optimize a synthetic approach to obtaining functionalized or difunctionalized aromatic vinyl phosphonic acids that is time- and cost-effective. The simple purification method yields target products by employing precipitation into dichloromethane, thus eliminating a need for labor- and solvent-intensive column chromatography, unlike the reported synthesis of [2-(9H-carbazol-9-yl)ethyl]phosphonic acid. The synthetic routes described herein allow simple control over the regiochemistry of the target VPA derivatives due to the use of bromo-carbazoles, dibromo-carbazoles, etc. as a starting material. The disclosed embodiments also are able to provide alkyl and vinyl linkages between the phosphonic acid group directly linked to the aromatic ring rather than the nitrogen in the carbazole. Furthermore, the herein described process can attach a plethora of groups to the 9-position of the carbazole.

Aromatic vinyl phosphonic acid derivatives as disclosed herein have carbazole and phosphonic acid groups similar to [2-(9H-carbazol-9-yl)ethyl]phosphonic acid (2PACz), but the side chain with the phosphonic acid group is directly linked to the aromatic ring rather than the nitrogen in the carbazole. Without wishing to be bound by any particular theory, the present inventors hypothesize that this structural difference makes the compounds disclosed herein more flexible than 2PACz and allows a flat orientation after binding with the transparent conductive oxide (TCO) surface, thus promoting better interaction of nitrogen with Pb²⁺ in the perovskite. In addition, attaching phosphonic acid to the aromatic moiety allows different functionalization on the N-position of the carbazole. The synthetic methods disclosed herein are therefore advantageous in that they utilize inexpensive chemicals, mild reaction conditions suitable for various functional groups, and simple purification steps.

As further described elsewhere throughout this disclosure, the introduction of stronger bonding molecules at the buried interface according to embodiments of the present disclosure reduces the amorphous phase around the perovskite/hole-transporting material/ITO interface and suppresses cation migration under UV light. With the hybrid hole-transporting material EtCz3EPA/PTAA:BCP in the small area perovskite solar cells, the Too lifetimes measured under LED and LEP lamps were increased to approximately 4,610 and approximately 1,780 hours, respectively. The best-performing minimodule with the hybrid hole-transporting material formed according to embodiments of the present disclosure retained operational efficiency of approximately 17.5% after 10 weeks of outdoor testing.

The concepts disclosed herein are further described by way of the following non-limiting Examples, which are provided only for the purpose of illustrating specific embodiments of the present disclosure and in no way limit the scope or breadth of the disclosure.

### Example 1

To evaluate the indoor and outdoor durability of perovskite solar cells, small area perovskite cells solar were fabricated with a p-i-n structure of ITO/PTAA/FA_{0.9}Cs_{0.1}PbI₃/C₆₀/Bathocuproine (BCP)/Copper (Cu). The UV component in most commercial LED lamps traditionally used for indoor testing of perovskite solar cells is extremely weak, constituting <0.1% of the total light, far lower than the approximately 4.6% UV light in the solar spectrum. After indoor light soaking under an LED lamp at 60±5° C. and open-circuit (OC) conditions for approximately 200 hours, the small area perovskite solar cells with polyisobutylene (PIB) blanket encapsulation retained approximately 103% of the initial efficiency, consistent with prior results.

In striking contrast, small area perovskite solar cells with the same encapsulation which were tested under open-circuit conditions outdoors, when there was an average daytime temperature of approximately 20° C., showed a reduction in efficiency by approximately 21% after only 10 days. The degradation of the small area perovskite solar cells was mainly from the reduced short-circuit current density (J_{SC}) and fill factor (FF).

TABLE 1
Parameters of J-V curves from PTAA-based perovskite solar
cells with different illumination time under LEP lamp

| Samples | J_{SC} (mA cm⁻²) * | V_{OC} (V) | FF | PCE (%) |
|---|---|---|---|---|
| 0 hr | 24.80 | 1.11 | 0.81 | 22.36 |
| 10 hr | 24.68 | 1.11 | 0.78 | 21.43 |
| 20 hr | 24.57 | 1.10 | 0.76 | 20.54 |

* These perovskite solar cells with an active area of 0.08 cm² were measured without any antireflection layer. The light intensity of LEP lamp was calibrated to approximately 100 mW/cm² (3.5% UV inside) and the temperature was approximately 60° C.

The main difference between the indoor and outdoor testing should be the temperature, light source, and the light cycling. However, the temperature difference should not be the reason for the huge difference between outdoor and indoor stability which was observed, because the outdoor temperature was lower than the indoor temperature. In addition, the small area perovskite solar cells using the same structure lasted less than 3,000 hours under thermal light test at 60±5° C. After 10 cycles of standard light cycling (ISOS-LC-1) testing, the small area perovskite solar cells kept approximately 105% of initial efficiency, which excludes the light cycling as the main reason for the fast degradation of the small area perovskite solar cells in the outdoor test. Thus, the elevated UV component in sunlight compared to an LED lamp should be the main reason for the much faster degradation of the small area perovskite solar cells.

To confirm this, a light emitting plasma (LEP) lamp (which emits light comprising approximately 3.5% UV light) was used to simulate sunlight. After converting the small area perovskite solar cells with a long-pass optical filter with a cut-off wavelength of approximately 435 nm, the rapid degradation disappeared at the initial stage, confirming that UV light is responsible for the accelerated degradation of the small area perovskite solar cells in the outdoor test. Without wishing to be bound by any particular theory, it is believed that UV light may damage primary chemical bonds in PTAA, perovskites, or the secondary bonding at the ITO/PTAA/perovskite interface.

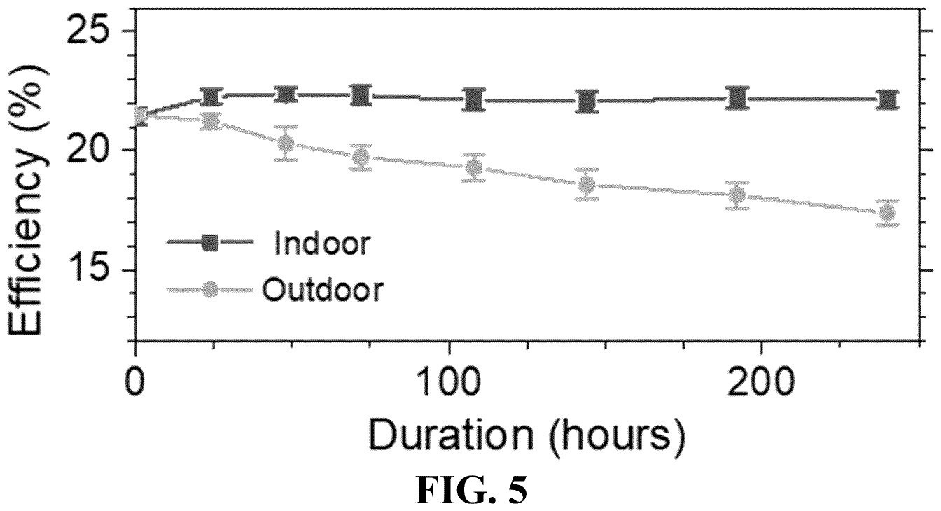

To determine which of these possible causes dominate the UV-induced degradation of the perovskite solar cells, PTAA powder (poly[bis(4-phenyl)(2,4,6-trimethylphenyl)amine]) was exposed to a UV lamp (390-400 nm) with a light intensity of approximately 10 mW/cm² in N₂ atmosphere for approximately 200 hours. Then the UV-irradiated PTAA powder was used to fabricate a perovskite solar cell. Changes in the absorption spectra of the PTAA were used to characterize the degree of damage to the PTAA layer by UV light illumination. PTAA shows an adsorption in the wavelength range of lower than 425 nm. The absorption peak of the PTAA film prepared from the UV-irradiated PTAA was reduced by approximately 45%, indicating UV damage. The perovskite solar cell made using the UV-irradiated PTAA lost only about 0.5% of its efficiency compared to the reference perovskite solar cell. This efficiency reduction is nearly ten times smaller than that shown in FIG. 5 and is mainly from the open-circuit voltage (V_{OC}) reduction. In contrast, the efficiency loss experienced by the perovskite solar cells tested outdoors was dominated by the reduction of J_{SC} and FF, suggesting a different degradation mechanism.

The film stability and efficiency evolution of perovskite with In³⁺ surface processing were investigated, as the present inventors hypothesize that the In³⁺ ions in ITO may leach into perovskite under UV treatment and cause the damage to the perovskite. The perovskite films with InBr₃ surface treatment did not show faster color changes (such as yellowing) under the LEP lamp than samples with FABr surface treatment. The durability of the perovskite solar cells showed a similar trend, indicating it is unlikely that In³⁺ introduced additional perovskite damage. Therefore, the accelerated degradation of the perovskite solar cells in the outdoor test comes from either fast degradation of the perovskite itself or the breakdown of the weak interface between perovskites and the underneath ITO/PTAA substrates.

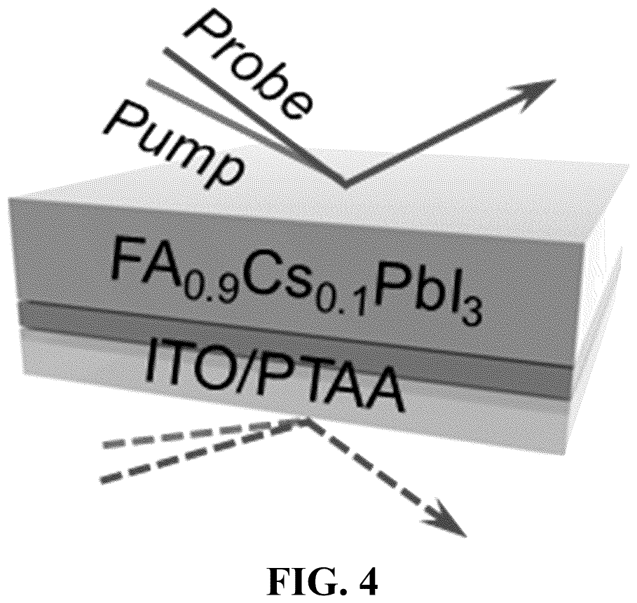

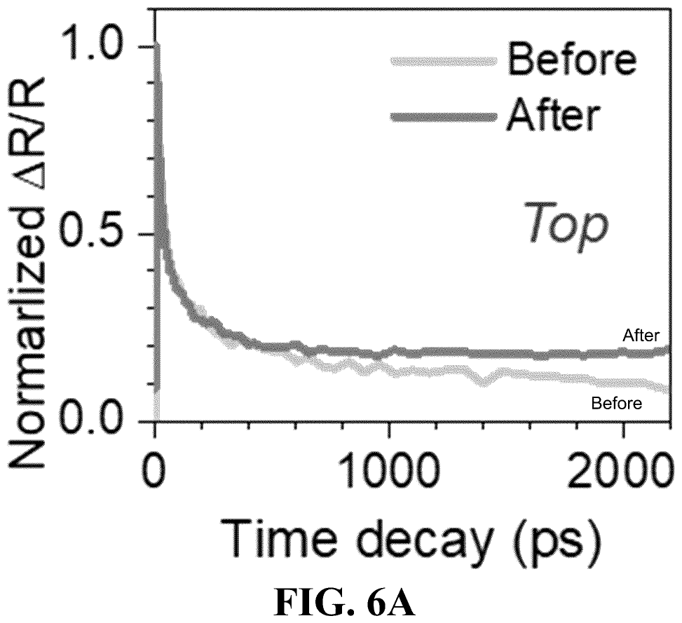

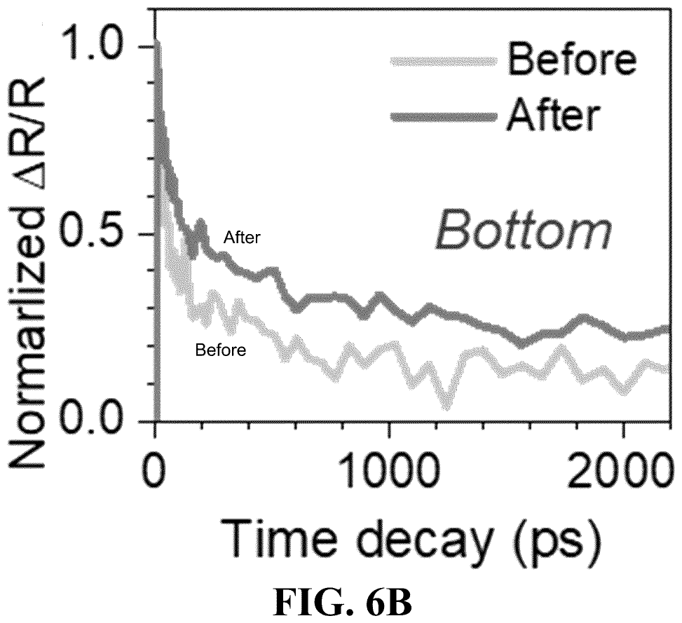

By observation with the naked eye, the ITO side of the perovskite solar cells changed from a dark color initially to a gray color after the simulated outdoor test for approximately 200 hours under the LEP light (approximately 3.5% UV, approximately 100 mW/cm², 60±5° C., OC conditions), indicating remarkable changes in the perovskite layer. To understand the material change, transient reflectance spectroscopy (TR) analysis was performed on perovskite films before and after light soaking. The perovskite films were deposited on ITO/PTAA substrates and illuminated from the ITO side. As illustrated in FIG. 4, the perovskite film was excited and probed from the top side (perovskite/air) and bottom side (ITO/PTAA) with a pump laser wavelength of 400 nm, which penetrates greater than 50 nm into the perovskites, and the results are shown in FIGS. 6A and 6B. In TR experiments, the probe penetrates only approximately 20 nm of the perovskite, and with short wavelength excitation, the fast initial decay of the amplitude represents carriers moving out of the probing region, i.e., carrier diffusion from the surface to the bulk, where the longer time kinetics represent the total carrier density decay reflecting both surface and bulk recombination. No changes were observed of the fast decay when light enters from the perovskite/air side, which indicates no degradation of perovskite within the region of probing, i.e., at the top surface. The longer time decay improves after 300 hours of LEP light soaking, which most likely indicates improved surface recombination. When probing the perovskite/PTAA/ITO side, there is a notably slower decay in the fast component after 300 hours, indicating that a large reduction in carrier mobility (i.e., slower carrier diffusion away from the surface) has occurred in the perovskite close to the PTAA side after photodegradation.

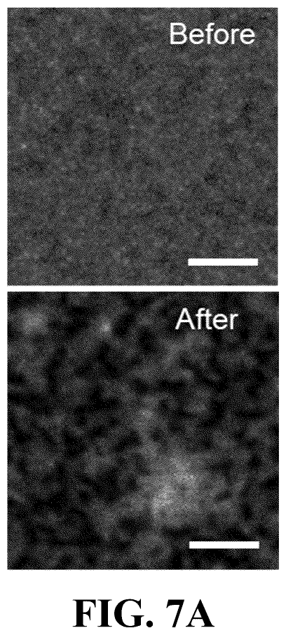

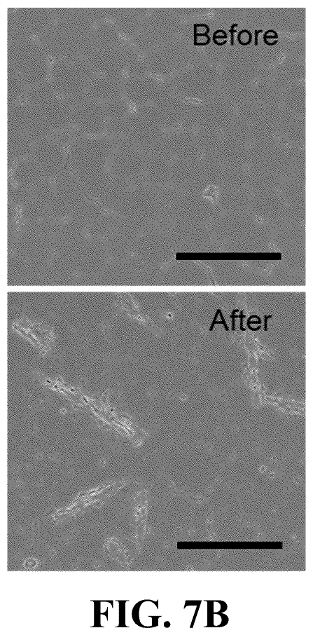

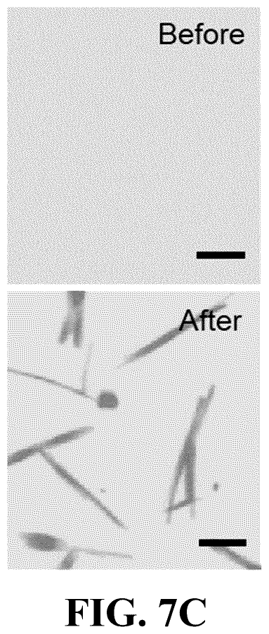

Microscopic studies were then conducted to further investigate the changes at the bottom of the perovskite layer. After approximately 200 hours of LEP light soaking, many dark regions appeared in photoluminescence (PL) mapping (FIG. 7A). From the scanning electron microscope (SEM) images, several needle-shaped regions emerged at the bottom of the perovskite films, which is different from the morphology of pristine FAI₋ₓ CsₓPbI₃ (FIG. 7B). Similar morphologies were also observed on X-ray fluorescence (XRF) mapping (FIG. 7C), where these needle regions have higher Cs/I element ratios, indicating the presence of serious segregation of A-site cations. A weak phase segregation was also observed in FA₁₋ₓCsₓPbI₃ under the LEP lamp by PL mapping but only after 2000-3000 hours. The much more severe and faster phase segregation under the LEP lamp indicates that UV light accelerated the migration of A-site cations and phase segregation by tens of times.

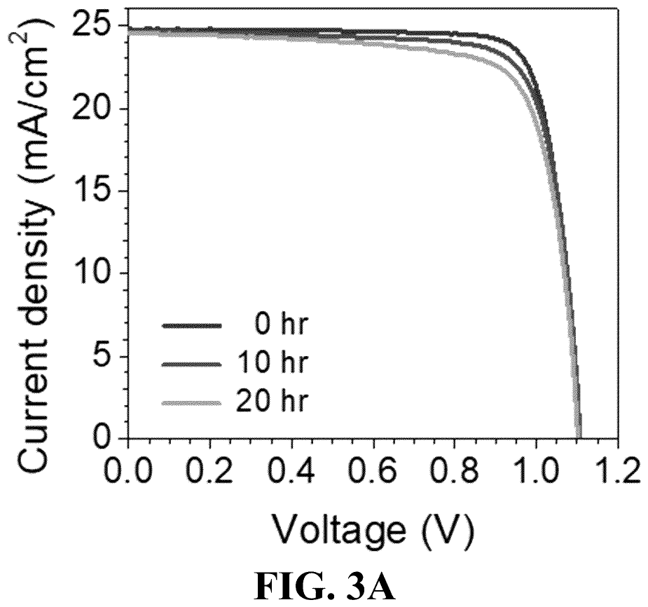

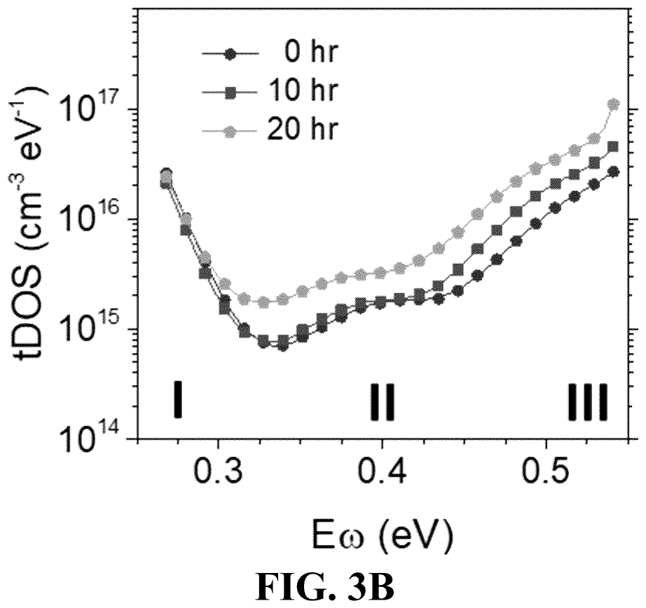

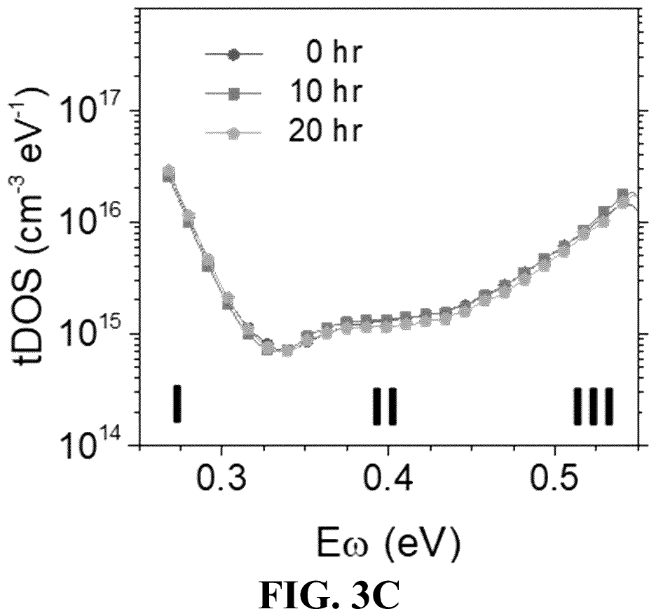

To determine why and how UV light accelerated the phase separation of A-site ions, the evolution of J-V curves and the trap density in the perovskite solar cells with PTAA as the hole-transporting material was studied. The perovskite solar cells were light soaked under an LEP light with a light intensity of approximately 100 mW/cm² at approximately 60° C. With the increased light exposure time from 0 to 20 hours, the efficiency of the perovskite solar cells decreased monotonically (FIG. 3A). The trap density of state (tDOS) of the perovskite solar cells was measured by thermal admittance spectroscopy (TAS) (FIGS. 3B and 3C), and typically consists of three distinct trap bands (I, II, and III), representing Iᵢ_{^{−}} defects, Iᵢ_{⁺} defects, and defects related to amorphous regions close to the bottom interface, respectively, in iodide-based perovskite solar cells.

As shown in FIG. 3B, defects in all trap bands monotonically increased, which is consistent with the trend in the efficiency reduction of the perovskite solar cell. The initial large background Iᵢ_{^{−}} density makes the change less distinct for Iᵢ_{⁺} defects. Nevertheless, the dramatic increase of already high-density trap band III indicates the perovskites close to the bottom interface became much more amorphous. FIG. 3C shows the variation of the trap densities of state of the perovskite solar cells made in the same batch but exposed to LED lamps of the same light intensity. Only a very small change in trap band II was observed, but no notable change was observed for trap bands I and III. All these studies show that the UV light-induced degradation of perovskite solar cells is caused by damage to the ITO/PTAA/perovskite interface.

The weak interaction of perovskites with PTAA and ITO at the bottom is damaged for the perovskite solar cells under UV light, making the buried perovskite interface resemble the top perovskite surface by forming dangling bonds. This further results in faster ion migration at the bottom of the perovskite films. This weak interaction accelerates the phase segregation, breaks down the perovskite structure, and generates more point defects. The IA defects can trap photogenerated electrons, leaving excess holes for the perovskite solar cells under illumination. Excess holes are shown to accelerate the migration of the A-site cations, and eventually causes the migration and segregation of the cations at the bottom of the perovskite films.

In summary, the UV induced perovskite degradation mechanism was identified. In response, a stronger interconnection layer was introduced to the perovskite solar cells of the present disclosure to improve the outdoor stability of the perovskite minimodules. UV light directly damaged the interface of the perovskite and the substrate, which resulted in inefficient hole extraction and accelerated the A-site cation migration.

### Example 2

Photocurrent measurement and J-V characteristics of perovskite solar cells and perovskite solar cell minimodules of embodiments of the present disclosure were performed using a xenon-lamp based solar simulator (Oriel Sol3A, Class AAA Solar Simulator). The output light intensity was calibrated to approximately 100 mW cm⁻² by a silicon reference cell (Newport 91150V-KG5). All devices were measured using a Keithley 2400 source meter with a backward scan rate of approximately 0.1 V s⁻¹ in air at room temperature.

Several characteristics of sample perovskite solar cells were measured. All samples of the perovskite solar cells that were measured, except for the samples measured by scanning electron microscope (SEM), were encapsulated by a polyisobutylene (PIB, HelioScal PVS 101) blanket with a laminator (LAB-LAMINATOR L036LAB) at approximately 110° C. for approximately 10 minutes. In contrast, the SEM samples were encapsulated with epoxy (Devcon 14250) and cover glass.

For the stability measurement, a white LED lamp with radiation light wavelength of 400-850 nm was used for indoor stability testing. A light emitting plasma (LEP) light with radiation light wavelength of 320-950 nm was used to simulate the sunlight indoors.

The temperature of the perovskite solar cells of some embodiments were heated up to approximately 60° C. by the lamps. In at least some embodiments, no temperature controller was applied to the perovskite solar cells.

The outdoor test of the small area perovskite solar cells was conducted at a time and place with daytime temperatures of approximately 20° C. All of the small perovskite solar cells were tested under open-circuit (OC) conditions and without any resistance load.

The perovskite solar cell minimodules were deployed on a fixed-tilt rack. They were actively loaded at their maximum power point (MPPT), except at night when they were kept at short circuit. There was no temperature, spectrum, angle of incidence, or other corrections applied to the testing system. The damp-heat stability and thermal cycling stability were both measured in an environmental chamber (the BTX475 produced by ESPEC).

The transient reflection measurements were performed by a pump-probe spectrometer. The fundamental laser pulse with wavelength at approximately 800 nm was generated by a Ti:sapphire amplifier. The pulse repetition rate was approximately 1 kHz. The fundamental pulse was then split into two parts by a beam splitter. One part was sent to an optical parametric amplifier for the pump generation. The pump was chopped at a frequency of approximately 500 Hz and attenuated by neutral density filter wheels.

The other part of the fundamental pulse was focused into a sapphire crystal to generate a white-light continuum (430-820 nm) that was used as the probe. The probe pulses are delayed in time with respect to the pump pulses using a motorized translation stage mounted with a retroreflecting mirror. The pump and probe spatially overlapped on the surface of the sample. The incident angle for both pump and probe was around 45°.

The reflected probe pulses were directed to the multichannel complementary metal-oxide-semiconductor sensor. The size of the focused spot at the sample position for the probe and pump beams was around 200 μm and 600 μm, respectively. The total pump-photon flux was determined by measuring the pump power after a pinhole with a radius of 200 μm was created at the sample position. The input photon flux was obtained by subtracting the reflected photon flux from the total photon flux. The average excitation density was calculated as the ratio of input photon flux to the pump penetration depth.

For photoluminescence (PL) and mapping, the PL signal was detected by a PicoQuant PMA Hybrid single photon counting module with TCSPC technology. PL mapping was conducted with PicoQuant MicroTime 100 and FluoTime 100 system at room temperature. PicoQuant PDL 828 “Sepia II” multichannel diode laser was used as the laser source and approximately 405 nm pulsed laser was used for the measurements.

For the scanning electron microscope measurement, SEM images were taken on an FEI Helios 600 Nanolab Dual Beam System. For SEM characterization, the accelerating voltage of electron beam was approximately 5 kV, and the current was approximately 86 pA. For the preparation of the SEM samples, the small perovskite solar cells were first encapsulated with epoxy and cover glass. After the epoxy was cured, the contact between epoxy and Cu/BCP/C60 became much stronger than the interaction between the perovskite and the hole-transporting material. The perovskite could thus be peeled off from the perovskite/hole-transporting material interface or the perovskite layer when a tensile force was applied to the cover glass side and ITO side, respectively.

Nanoprobe X-ray fluorescence measurements were taken using a focused X-ray probe with approximately 250 nm full-width half maximum (FWHM) inside of a helium filled enclosure. The X-ray energy was set to approximately 7 keV to maximize sensitivity to the Cs-L and approximately I-L absorption edges. Full X-ray fluorescence spectra were taken at each point and MAPS software was used to fit these spectra and fit the contributions of overlapping fluorescence signals. NIST 1832 and 1833 fluorescence standards were used to quantify the abundances of Cs and I within the film.

Thermal admittance spectroscopy (TAS) and drive level capacitance profiling (DLCP) measurements were performed by an Agilent E4980A precision LCR meter. The DLCP measurement was conducted in the DC bias range of 0 V to 1.2 V (near VOC), while the amplitude of the AC biases ranged from 20 to 200 mV. For each AC bias, an additional offset DC voltage was applied to keep the maximum forward bias constant. The measured capacitances at each DC bias were collected.

For the TAS measurement, the DC bias was fixed at approximately 0 V and the amplitude of the AC bias was approximately 20 mV. The scanning range of the AC frequency was 0.02 to 2000 KHz.

Atomic force microscope-infrared spectroscopy (AFM-IR) of the surface was measured by a Bruker nanoIR3 with contact mode. The IR laser range was from 900 to 1900 cm 1. The IR input power was approximately 0.5 and 0.82%. The measurement was first calibrated by a PTAA sample for accurate topography, phase, and IR images. After calibration, the bare ITO, PTAA on ITO, EtCz3EPA on ITO, and hybrid hole-transporting material on ITO were measured. After selecting distinguished IR peaks, 1028 cm 1 for PTAA and 1012 cm 1 for EtCz3EPA, topography, phase, and IR image of the four samples were measured.

Nuclear magnetic resonance spectroscopy (NMR) spectra were recorded on JEOL ECA-500 (500 MHz) spectrometers at room temperature. The ultraviolet-visible (UV-Vis) spectra were recorded on a Beckman Coulter DU 800 spectrophotometer, samples were prepared using chloroform as solvent. Emission spectra were obtained using a Horiba Jovin Yvon Nanolog spectrofluorometer with THE as solvent.

The above-described investigations revealed that direct use of EtCz3EPA to replace PTAA resulted in poor performance of perovskite solar cells. The poor performance of the perovskite solar cells which include EtCz3EPA is attributed mainly to the conductivity and hole extraction capability of EtCz3EPA which performed much worse than the PTAA it replaced.

Since excess holes play a critical role in the UV-accelerated perovskite degradation, an EtCz3EPA/PTAA:BCP hybrid hole-transporting material was applied in the perovskite solar cells of embodiments of the present disclosure, in which a layer of BCP doped PTAA is coated on EtC23EPA. The present inventors found the EtCz3EPA/PTAA:BCP hybrid hole-transporting material significantly enhanced efficiency and stability of the perovskite solar cells of the present disclosure.

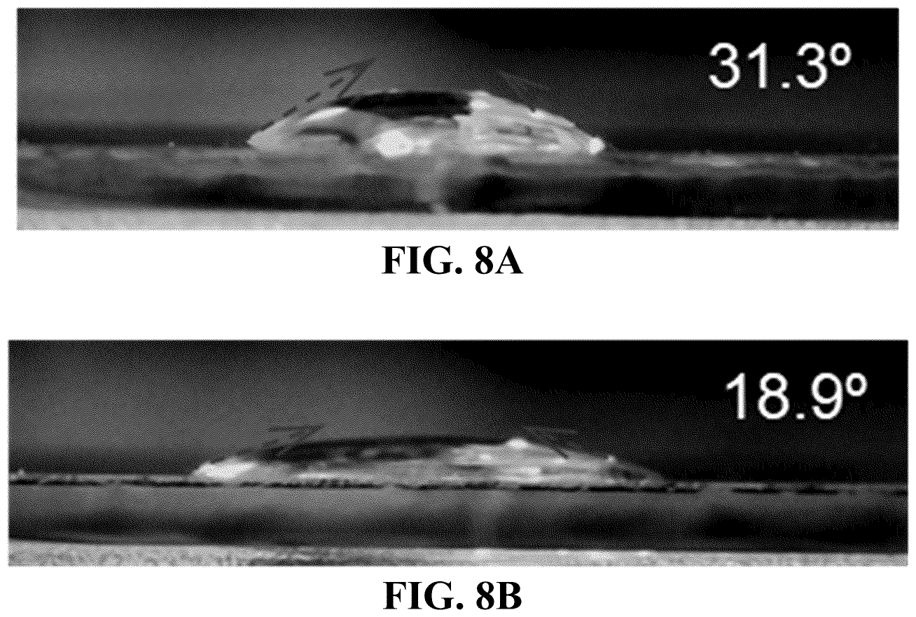

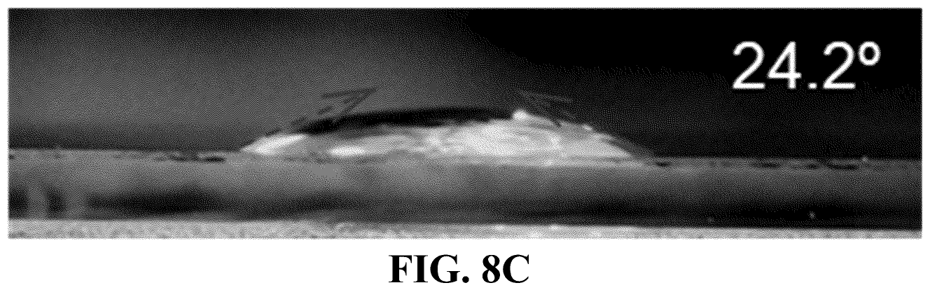

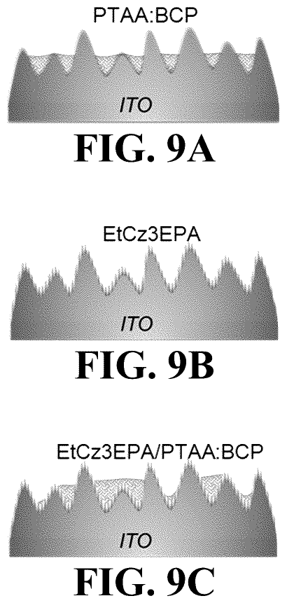

In some embodiments, bathocuproine (BCP) was added into PTAA to improve the structural stability of perovskites at the bottom interface due to the chelation of BCP with lead ions. However, BCP itself does not enhance interaction of perovskite with ITO, because BCP cannot interact with ITO. The contact angle measurement results show that FAPbI₃ solution has much better wetting on EtCz3EPA than on PTAA:BCP (FIGS. 8A-8C). The contact angle of the hybrid hole-transporting material is in between, suggesting that the PTAA:BCP layer on the top of EtCz3EPA is likely non-continuous, as shown in FIGS. 9A-9C, which provides enough space for the contact of perovskite and the bottom EtCz3EPA layer.

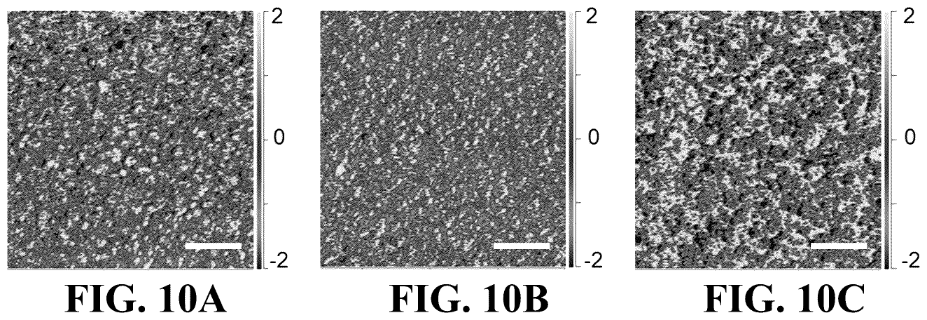

Atomic force microscope-infrared spectroscopy (AFM-IR) measurements were taken to understand the distribution of the hole-transporting material layer on the ITO substrate. The infrared signal was collected from the peak of approximately 1012 or approximately 1028 cm⁻¹, which corresponds to the C—H bending vibrations in —CH₃ group. As shown in FIGS. 10A-10C, neither PTAA:BCP nor EtCz3EPA exhibit homogeneous coverage on ITO substrate. EtCz3EPA shows a weaker signal due to its smaller thickness. PTAA:BCP coated on the EtCz3EPA layer was much less continuous, leaving open regions to expose EtCz3EPA, which allows the immediate contact of EtCz3EPA with perovskite. The diameter of the exposed EtC23EPA region is small enough so that photogenerated holes can still diffuse to PTAA:BCP for efficient collection.

Perovskite films were then deposited onto different hole-transporting materials to check the bonding strength of perovskites with the ITO/hole-transporting material substrates, which was evaluated by a peeling-off method. The present inventors observed that perovskites made on PTAA are very easy to peel off from the perovskites/ITO interfaces. In contrast, the perovskite films made on EtCz3EPA-only or the hybrid hole-transporting materials were not completely peeled off from ITO substrate, indicating the stronger adhesion of perovskites with ITO and the EtCz3EPA linker. As will be appreciated by one of skill in the art, voids close to the embedded interface could be generated after long-term light soaking or thermal annealing mainly due to the recrystallization of amorphous perovskites.

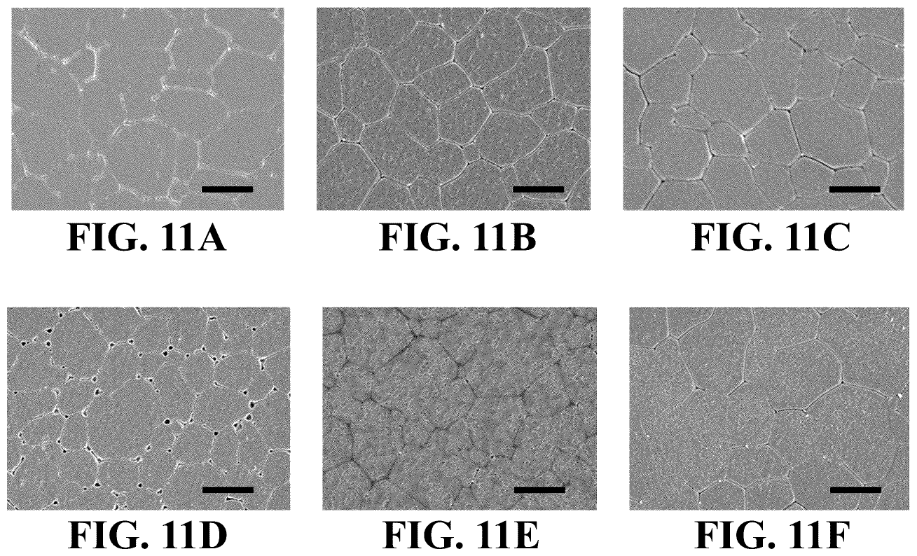

In some embodiments, samples were annealed in the dark at approximately 85° C., which drove the evaporation of residual dimethyl sulfoxide (DMSO) and the recrystallization. For perovskite solar cells formed with EtCz3EPA-only or hybrid hole-transporting materials, the peeled-off perovskite films did not show voids in either pristine samples or in samples observed after approximately 1,000 hours of thermal annealing at approximately 85° C. (FIGS. 11A-11C).

In contrast, the perovskite film grown on PTAA:BCP showed many voids with a size of 30 nm to 100 nm formed around the grain boundaries after the annealing process. Therefore, the perovskites grown on EtCz3EPA have much less amorphous perovskites, indicating the EtC23EPA affected the crystallization process of perovskite, which is consistent with the result from the grazing incident X-ray diffraction patterns.

The bottom surfaces of perovskites peeled from hybrid hole-transporting materials were rougher than those from PTAA:BCP regardless of annealing process, as shown in the SEM images in FIGS. 11B and 11E. This bottom surface roughness indicates that facture of perovskites occurred in some regions where perovskites stick strongly to ITO during the peel-off process. This again confirms the stronger interaction of EtCz3EPA with both ITO and perovskites than PTAA:BCP. Moreover, the bottom surface of the 2PACz-based sample was smoother than that of the EtCz3EPA-based sample, further demonstrating the difference in the binding strength of the two molecules with perovskites, which explains why the EtC23EPA-based devices have better light-soaking stability under an LEP lamp.

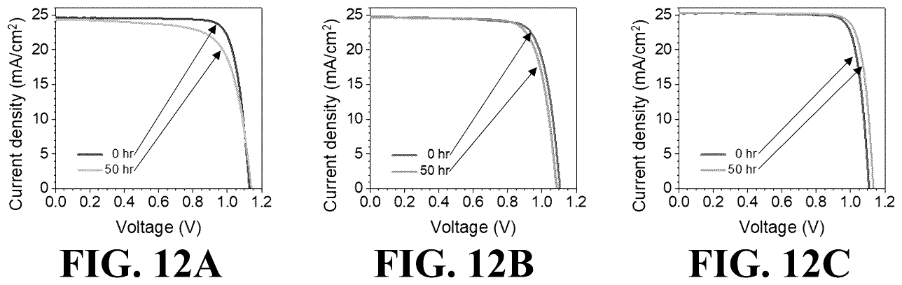

FIGS. 12A-12C show the J-V curves of the fresh and light-soaked perovskite solar cells with different hole-transporting materials. After 2 days of testing under an LEP light, the PTAA:BCP-based perovskite solar cells showed decreased fill-factor (FF) and approximately 9% of power conversion efficiency (PCE) loss. In contrast, the EtCz3EPA-based perovskite solar cells showed decreased VOC and only approximately 1% of PCE loss.

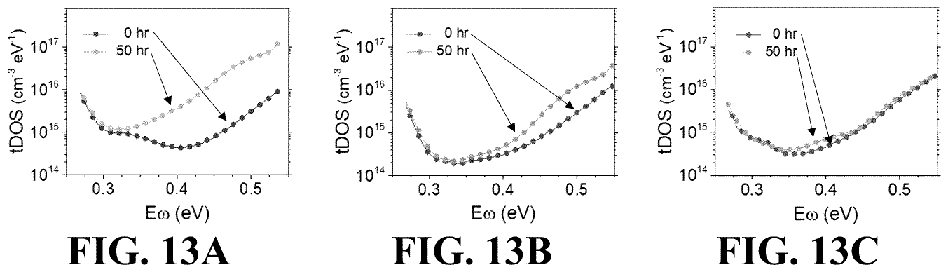

BCP can only bond to perovskites but has barely any interaction with ITO, leading to a similar variation trend for J-V curves from PTAA:BCP- and PTAA-based perovskite solar cell devices. This highlights the importance of the connection between ITO, the hole-transporting material, and perovskites. Although the trap density of the EtC23EPA-based perovskite solar cells is significantly lower than those of the PTAA:BCP-based perovskite solar cell devices, trap bands II and III still increased after light soaking (FIGS. 13A-13C), which is consistent with the evolution of perovskite solar cell efficiency, suggesting that the ITO/perovskite interface has not been effectively stabilized under UV light by the BCP addition.

When the thin EtC23EPA was covered by PTAA, the fast component of the PL lifetime was reduced to approximately 60% of the EtCz3EPA only perovskite solar cell samples and the perovskite solar cell was successfully stabilized under LEP light, which indicates that fast hole extraction is crucial for better UV stability. The trap density of the EtCz3EPA/PTAA:BCP-based perovskite solar cells did not have a remarkable increase after illumination, consistent with J-V results.

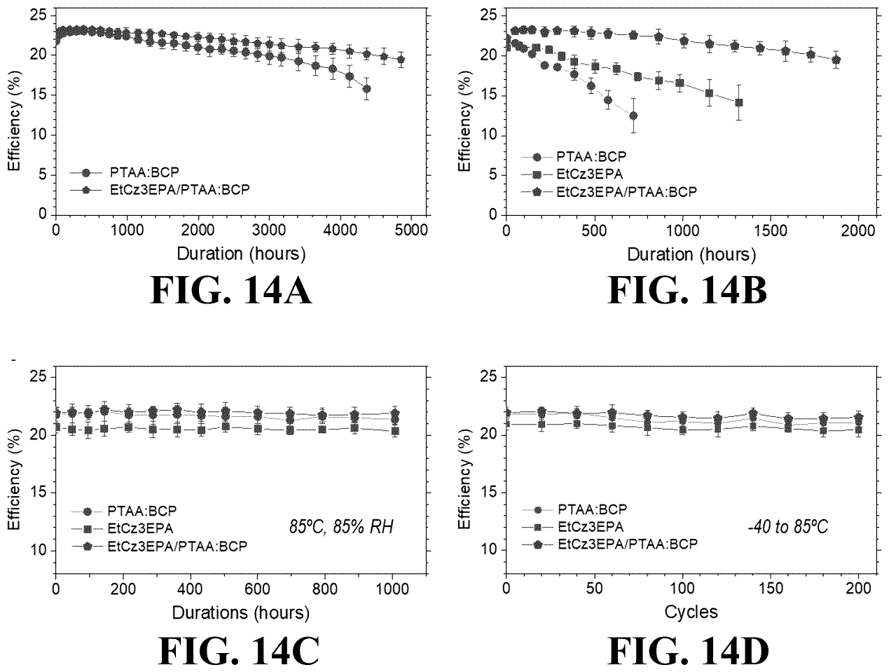

The light soaking stability of these perovskite solar cells with an active area of approximately 8 mm² was measured to evaluate the long-term stability. As shown in FIG. 14A, the PTAA:BCP-based perovskite solar cells showed a T₉₀ lifetime of approximately 3,240 hours under an LED lamp, which is consistent with previous results based on lead-chelation molecules. The hybrid hole-transporting materials-based perovskite solar cells have an increased T₉₀ lifetime of approximately 4,610 hours. Under LEP light with approximately 3.5% UV, the PTAA:BCP-based perovskite solar cells showed a Too lifetime of approximately 190 hours. In contrast, perovskite solar cells with hybrid hole-transporting materials had a T₉₀ lifetime of approximately 1,780 hours (FIG. 14B).

A damp-heat stability test was also conducted at 85° C. and 85% humidity (ISOS-D-3) on PIB encapsulated small perovskite solar cells for 1,000 hours. This test not only examined the encapsulation quality but also the intrinsic heat stability of perovskites (FIG. 14C). The perovskite solar cells with all three types of hole-transporting materials showed less than 2% efficiency loss after 1,000 hours of testing. In addition, all the perovskite solar cells with the three types of hole-transporting materials passed the thermal cycling test with less than 2% efficiency loss after 200 thermal cycles between −40 and 85° C. (FIG. 14D).

TABLE 2
Parameters of J-V curves from perovskite solar cells
with different hole-transporting materials and different
illumination times under an LEP lamp

| Samples | | J_{SC} (mA cm⁻²) * | V_{OC} (V) | FF | PCE (%) |
|---|---|---|---|---|---|
| PTAA:BCP | 0 hr | 24.86 | 1.14 | 0.81 | 22.90 |
| | 50 hr | 24.59 | 1.15 | 0.72 | 20.29 |
| EtCz3EPA | 0 hr | 24.78 | 1.12 | 0.77 | 21.34 |
| | 50 hr | 24.63 | 1.10 | 0.75 | 20.64 |
| Hybrid HTM | 0 hr | 25.00 | 1.12 | 0.82 | 23.09 |
| | 50 hr | 25.02 | 1.15 | 0.83 | 23.77 |

* These perovskite solar cells with an active area of 0.08 cm² were measured without any antireflection layer. The light intensity of LEP lamp was calibrated to approximately 100 mW/cm² (3.5% UV inside) and the temperature was approximately 60° C.

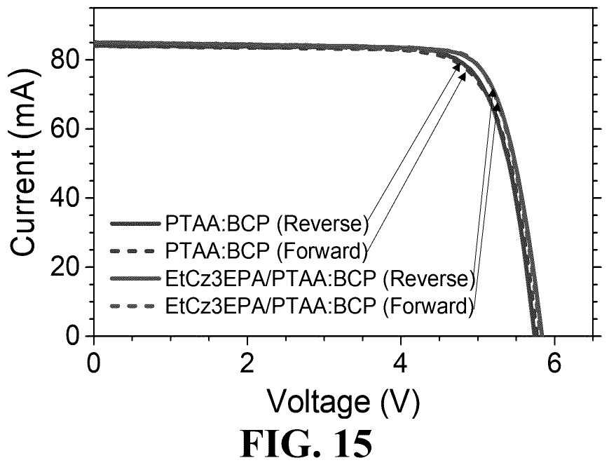

To evaluate the scalability and uniformity of hole-transporting materials, the hole-transporting material coating was upscaled and perovskite solar cell minimodules were fabricated with an aperture area of 15-50 cm². As shown in FIG. 15, the minimodule based on hybrid hole-transporting material showed an efficiency of approximately 22.1% measured at near room temperature, which is comparable to that of the PTAA:BCP-based minimodules (approximately 21.6%) after light soaking under 1 sun LED light for approximately 100 hours, revealing the good uniformity of the hybrid hole-transporting material.

In some embodiments, a polydimethylsiloxane (PDMS) film was applied as an antireflective layer on the surface of the ITO glass, which increased the photocurrent by approximately 6%. The PDMS film was removed during the following outdoor tests. The perovskite solar cell minimodules have the same encapsulation as the small area perovskite solar cells.

TABLE 3
Parameters of J-V curves from the minimodules
with different Hole-Transporting Materials

| | | | I_{SC} | V_{OC} | | PCE |
|---|---|---|---|---|---|---|
| Samples/subcells | | Scanning | (mA)* | (V) | FF | (%) |
| PTAA:BCP | 5 | Reverse | 84.03 | 5.74 | 0.80 | 21.58 |
| | | Forward | 84.19 | 5.77 | 0.79 | 21.32 |
| Hybrid HTM | 5 | Reverse | 85.05 | 5.82 | 0.80 | 22.09 |
| | | Forward | 84.96 | 5.81 | 0.80 | 21.97 |

*These minimodules were pre-illuminated by an LED lamp (approximately 100 mW/cm², <0.1% UV, approximately 60° C., OC conditions) for approximately 100 hours to achieve the highest efficiency and measured with PDMS anti-reflective layers, which increased the photocurrent by approximately 6%. The aperture area of the perovskite solar cell minimodules were 17.88 cm².

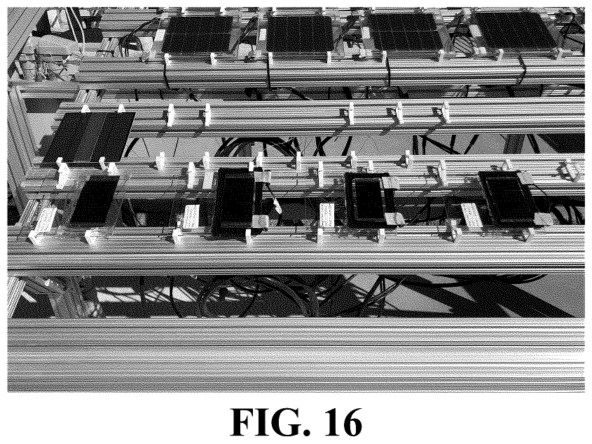

The encapsulated perovskite solar cell minimodules were then sent to the Perovskite PV Accelerator for Commercializing Technologies (PACT) center for independent outdoor testing. The perovskite solar cell minimodule efficiencies were measured outdoors over a period of four to five months, from late spring to early fall. The minimodules were deployed on a fixed-tilt rack. FIG. 16 shows a photo of the minimodules in the test field. The module surface temperature was monitored daily. Maximum module surface temperature reached approximately 50° C. during the summer. The perovskite temperature is higher than module surface temperature due to the heating of the perovskites by sunlight.

Using a hot plate to control the module surface temperature to be 40-50° C., the perovskite temperature was measured to approximately 8-10° C. higher using a solar simulator and a perovskite minimodule with the same size and encapsulation. The perovskite solar cell minimodules were actively loaded at their maximum power point, except at night when they were kept at short circuit. The irradiance was measured using a broadband thermopile pyranometer and used in efficiency calculations, which may yield a different efficiency to those measured under solar simulator. There was no temperature, spectrum, angle of incidence, or other corrections applied to the testing system.

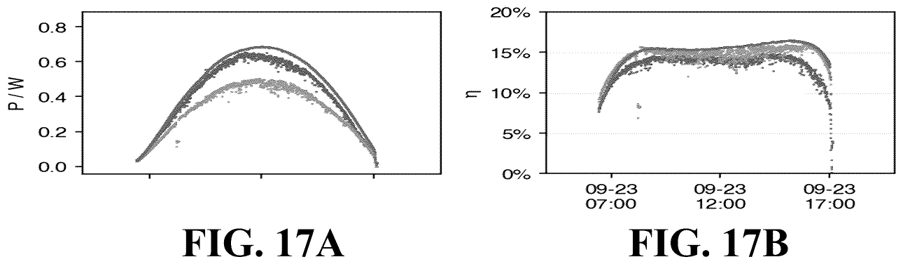

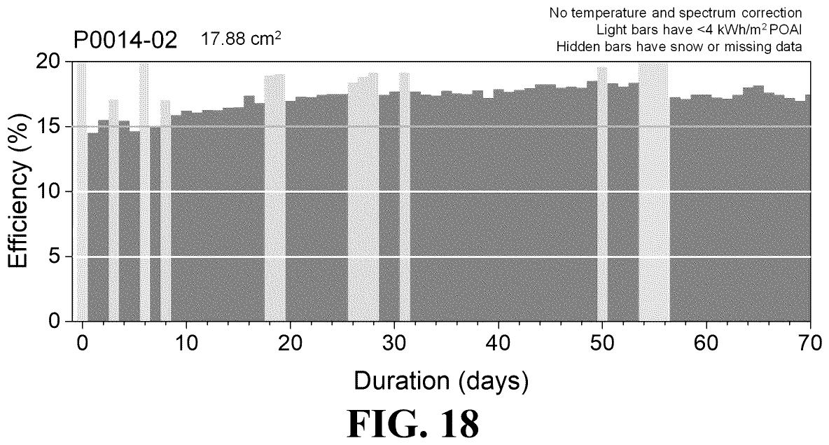

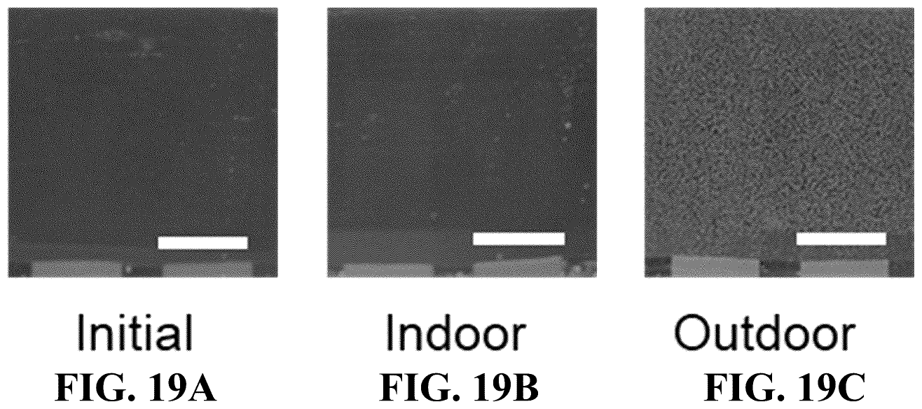

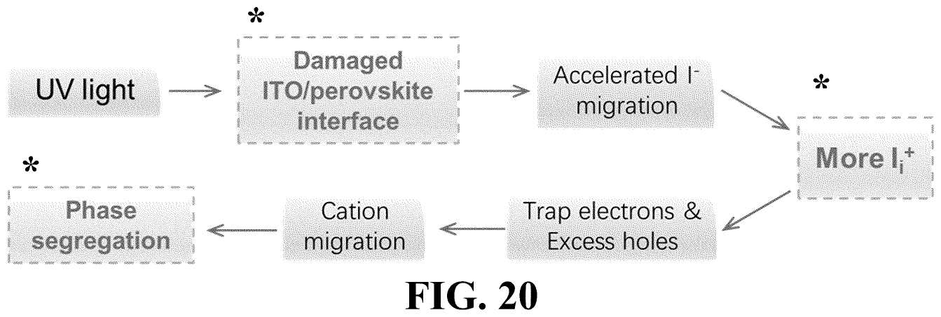

FIGS. 17A and 17B show the evolution of daily efficiency of the perovskite solar cells measured in outdoor conditions. For a daily output evaluation, the PCE of the perovskite solar cell minimodules stayed at a plateau of less than 18% for about 8 hours. As shown in FIG. 18, the perovskite solar cell minimodules remained efficient after 10 weeks of outdoor testing. The daily PCE of the perovskite solar cell minimodules increased for the first several weeks of testing before it began declining which is a regular light soaking effect of this perovskite composition.

The initial efficiency of the perovskite solar cell minimodules (approximately 15%) at the operational temperature was measured after 7 weeks dark storage and was recovered to approximately 18% after light-soaking for 2 weeks in an outdoor testing field. It is noted that the efficiency of the perovskite solar cells measured in the testing field is different from those measured at room temperature at an indoor testing site due to the different light intensity, light spectrum, and temperature. The sensitivity of these perovskite solar cells to light intensity and temperature was tested using perovskite solar cell minimodules fabricated by the same process. The efficiency of perovskite solar cell minimodules is almost constant with light intensity from 20 to 100 mW cm⁻², but they showed a temperature coefficient of −0.32%° C.⁻¹, which is still better than that of silicon solar cells but larger than MAPbI₃-based minimodules. After 10 weeks of outdoor testing, the operational efficiency of the best perovskite solar cell minimodule was approximately 17.5%, and the average operational efficiency of all perovskite solar cell minimodules was above 16%. This is the longest-lasting minimodule tested to date.

### Example 3

Self-assembled molecules (SAMs) do not necessarily self-assemble on transparent conducting oxides with perfect packing. They are merely referred to as SAMs for simplicity. Without wishing to be bound by any theory, it is hypothesized that they are covalently bound to TCO by phosphonic acid or other function groups with a coverage much less than 100%, and there is no confirmation that they form a monolayer on TCO.

A series of SAMs were designed and synthesized based on the EtCz3EPA chemistry with phosphonic acid (PA) groups connected to different positions on a carbazole-based ring to systematically investigate how variations in molecular structure affect device performance.

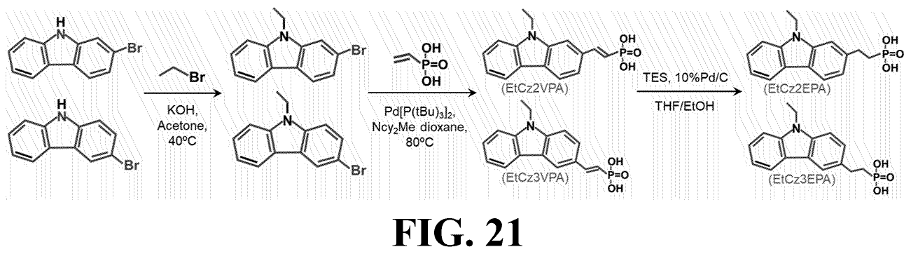

To clearly explore how the PA positioning impacts SAM properties, a series of molecules were designed, as shown in FIG. 21, with ethyl phosphonic acid (EPA) and vinyl phosphonic acid (VPA) moieties attached at the 2 and 3 positions of carbazole. The commercially available 2PACz, which has the EPA attached at the nitrogen 9-position, was studied here for comparison.

The synthesis of (E)-(2-(9-ethyl-carbazol-3-yl)vinyl)phosphonic acid (EtCz3VPA) and (E)-(2-(9-ethyl-carbazol-2-yl)vinyl)phosphonic acid (EtCz2VPA) can be efficiently achieved under mild conditions using readily available starting materials. One possible method is the coupling of the VPA linker to the aromatic carbazole moiety via the Mizoroki-Heck reaction, a well-established palladium catalyzed cross-coupling method. This reaction occurs between an alkene (VPA) and an aromatic halide (bromocarbazole). Though VPA can be coupled with a 9-alkylated carbazole at various positions (1, 2, 3, 4) on the aromatic ring, the substitution at the 2 and 3 positions were studied.

The reduction of the vinyl linker between the phosphonic acid and carbazole results in EtCz3EPA and (2-(9-ethyl-carbazol-2-yl)ethyl)phosphonic acid (EtCz2EPA). This reduction is accomplished using the commercially available mild reagent triethyl silane (TES), along with Pd/C and a protic solvent such as ethanol. The reduction products are isolated through precipitation into non-polar solvents like hexanes, or by extraction into basic media and reprecipitation into acidic water, providing good yields. These mild synthetic conditions are advantageous compared to the 2PACz method, allowing for the rapid production of a variety of tunable PA molecules that can be efficiently employed as SAMs in perovskite devices. FIG. 21 shows the detailed synthetic process and characterization of the molecules studied here: EtCz2VPA, EtCz2EPA, EtCz3VPA and EtCz3EPA.

Atomic force microscopy (AFM) was used to investigate the effect of PA position on the orientation and stacking of SAMs on substrates. Since the thickness variation is very small for monolayers among different orientations, during testing, very flat silicon (Si) wafers were chosen as the substrate. The molecules were deposited on Si with native oxides by a chemical bath method to form uniform layers, and the samples were washed multiple times (>10) in methanol to ensure that only a monolayer of molecules remain on silicon substrate and are strongly bonded to the oxide surface. The scribing process removes molecules from the substrate, resulting in clear differences in the height curves collected by AFM. The average value of the thickness is collected from 4-5 measurements.

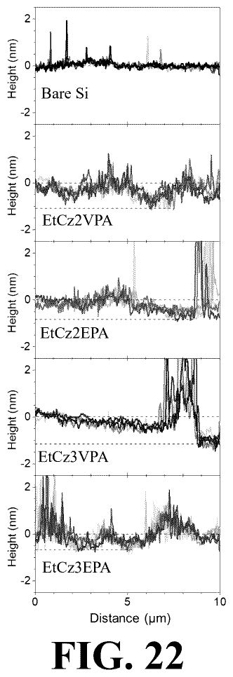

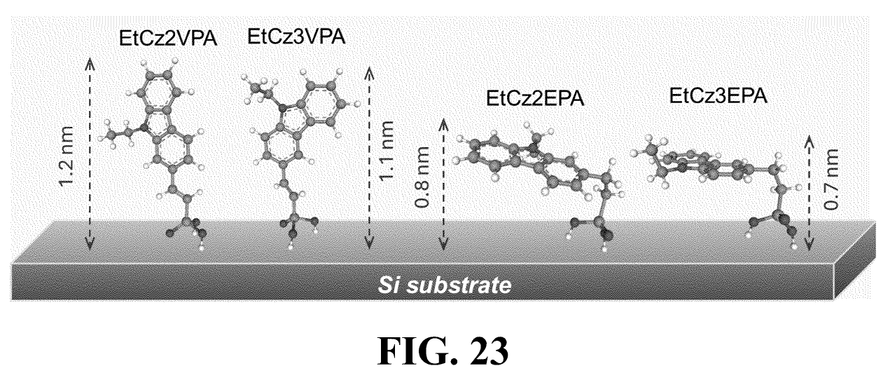

Sample height was observed after scribing, as shown in FIG. 22. The roughness of the Si wafer is ≤0.2 nm. In contrast, the average thicknesses of EtCz2EPA and EtCz3EPA layer on the substrate are 0.8 nm and 0.7 nm, respectively, which confirms that they formed a monolayer on the silicon substrate. The carbazole backbones in these two molecules should have face-on configuration to make the total thickness in this range, which is consistent with previous calculations of the relaxed molecular orientations of EtCz3EPA on the ITO substrate. In the structures of EtCz2VPA and EtCz3VPA, the rigid —(CH═CH)— conjugated bond connects the PA group to the carbazole ring, which makes the carbazole group difficult to lay down after the PA groups were bonded to the substrate, resulting in the edge-on configuration as shown in FIG. 23. This is consistent with the measured average molecule layer thickness of 1.2 nm and 1.1 nm, respectively for these two molecules.

The molecules with PA groups at carbazole 2-position (2-SAMs) have lower work function than those with PA groups at carbazole 3-position (3-SAMs), while the VPA based SAMs have lower work function than the EPA based SAMs.

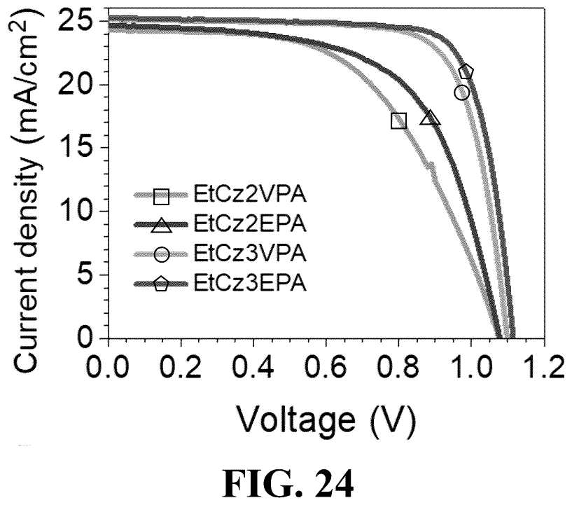

To evaluate the impact of the different molecules on device efficiency and stability, perovskite solar cells were fabricated with a p-i-n structure: ITO/HTM/FA_{0.9}Cs_{0.1}PbI₃/C₆₀/bathocuproine (BCP)/Copper (Cu). Multiple devices for each SAM based HTM were fabricated to extract the statistics. The small devices using 3-SAMs exhibited higher power conversion efficiencies (PCEs) compared to those with 2-SAMs, primarily due to larger fill factors (FF) and short circuit current density (JSC), as shown in Table 4 and FIG. 24.

TABLE 4
Parameters of J-V curves from perovskite
solar cells with different SAMs

| Samples | J_{SC} (mA cm⁻²) | V_{OC} (V) | FF | PCE (%) |
|---|---|---|---|---|
| EtCz2VPA | 24.14 ± 0.27 | 1.08 ± 0.01 | 0.57 ± 0.04 | 15.04 ± 1.16 |
| EtCz2EPA | 24.55 ± 0.28 | 1.09 ± 0.01 | 0.65 ± 0.03 | 17.27 ± 0.87 |
| EtCz3VPA | 24.98 ± 0.33 | 1.10 ± 0.01 | 0.74 ± 0.02 | 20.20 ± 0.59 |
| EtCz3EPA | 25.03 ± 0.25 | 1.10 ± 0.01 | 0.78 ± 0.02 | 21.37 ± 0.47 |

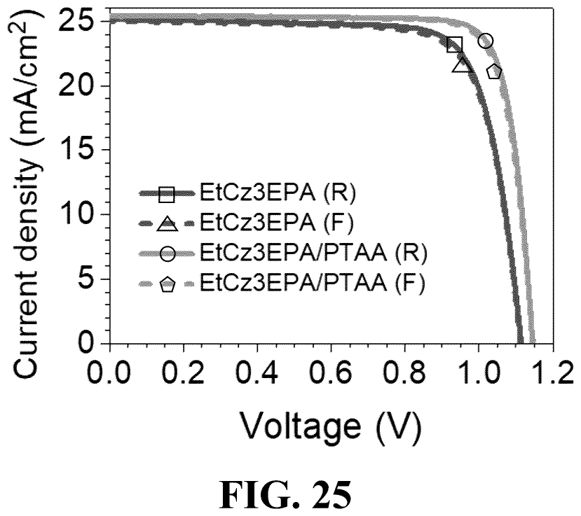

The results of Table 4 are consistent with the lower work functions of 2-SAMs, which resulted in higher series resistance in the small devices. Additionally, EPA-based devices demonstrated superior efficiency over VPA-based devices, which can be explained by the shorter hole transport distance from the perovskite layer to the ITO substrate, or thickness of the SAMs. Consequently, the small devices based on EtCz3EPA achieved the best average efficiencies of 21.37±0.47% with a fill factor of 0.78±0.02, outperforming all other SAM-based devices. Small devices were prepared with SAMs/PTAA hybrid HTMs, since they have proved to have better hole extraction and better devices efficiency and light-soaking stability. The devices based on EtCz3EPA/PTAA hybrid HTM showed efficiency of 24.19%, which is higher than that of the EtCz3EPA based device and neither of them showed photocurrent hysteresis, as shown in FIG. 25 and Table 5.

TABLE 5
Parameters of J-V curves from perovskite
solar cells with different HTMs

| Samples | | J_{SC} (mA cm⁻²) | V_{OC} (V) | FF | PCE (%) |
|---|---|---|---|---|---|
| EtCz3EPA | Reverse | 25.15 | 1.12 | 0.77 | 21.59 |
| | Forward | 25.08 | 1.12 | 0.76 | 21.21 |
| EtCz3EPA/ | Reverse | 25.43 | 1.15 | 0.83 | 24.19 |
| PTAA | Forward | 25.44 | 1.15 | 0.82 | 24.02 |

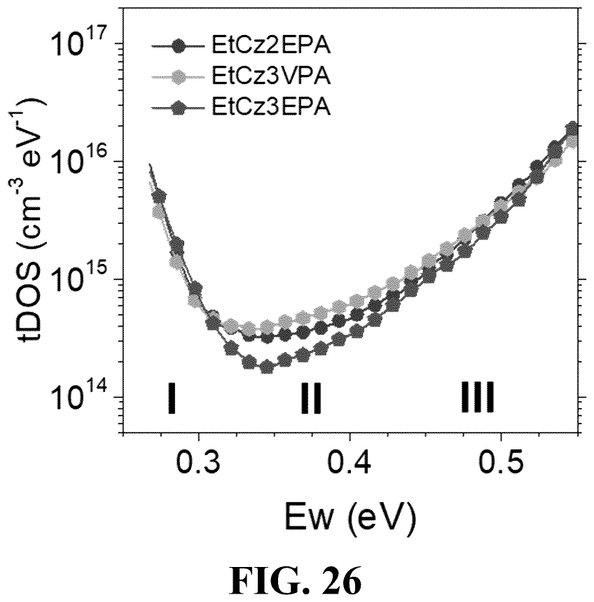

The trap density of states (tDOS) of the devices fabricated with different SAMs were checked by thermal admittance spectroscopy (TAS) (FIG. 26). The traces of the tDOS from all the iodide-based perovskite solar cells typically exhibited three distinct trap bands (I, II and III), representing the defect of Iᵢ_{^{−}}, Iᵢ_{⁺}, and defect related to amorphous regions near the SAMs/perovskite interface, respectively. Compared to the EtCz3VPA-based devices, the EtCz2EPA- and EtCz3EPA-based devices have lower trap densities at trap band II, suggesting the reduction of Iᵢ_{⁺} defects. Previous studies show that the Iᵢ_{⁺} defects are rich in grain boundaries and amorphous locations. Thus, without being bound to any particular theory, the present inventors hypothesize that the reduced Iᵢ_{⁺} defects could be attributed to the stronger interaction of the carbazole group with perovskites, thus improving the perovskite crystallinity close to ITO side, as observed previously.

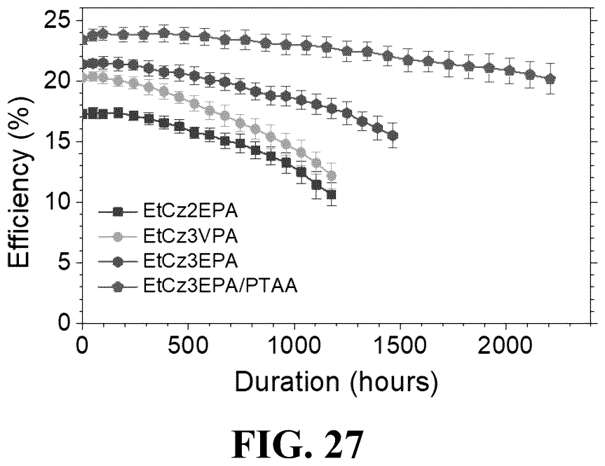

FIG. 27 shows the light-soaking stability of the small devices tested under open-circuit conditions using a light-emitting plasma (LEP) lamp (100 mW/cm²) which heated the perovskite solar cells to approximately 60° C. The spectrum of the LEP light source was the same as previous examples described herein, which contains approximately 3.5% UV light. The efficiency of EtC23VPA based devices decreased to 90% of the initial value after approximately 490 hours (T90). In contrast, the T90 lifetimes of devices based on EtCz3EPA extended to approximately 780 hours, which may be attributed to the enhanced interfacial bonding between the lying carbazole groups and perovskite. The T90 lifetime of EtC22EPA-based devices was approximately 560 hours, confirming that molecule orientation and stacking on the substrate influence the interface bonding between perovskite and SAMs, thereby affecting the device's thermal-light stability. The T90 lifetimes of the EtCz3EPA/PTAA based devices was approximately 1690 hours, which is consistent with the result obtained during previous testing by the inventors, and approximately 2.2 times of the EtCz3EPA based devices. Without being bound to any particular theory, the present inventors hypothesize that the improved Too lifetimes are attributed to better hole extraction reducing the presence of residual carriers, which eventually slows down the cation migration.

In summary, the present inventors designed and synthesized a series of carbazole-based molecules incorporating EPA and VPA groups at the 2- and 3-positions of carbazole. SAMs with PA anchor groups at the 3-position demonstrate reduced work functions of ITO/SAMs substrate, which effectively lowers series resistance and enhances the PCEs of perovskite solar cells. AFM analysis further reveals that molecules bearing EPA-functionalized carbazole units predominantly exhibit single-molecular stacking behavior, with their carbazole moieties adopting a face-on orientation relative to the substrate.

While various embodiments of the systems and methods have been described in detail, it is apparent that modifications and alterations of those embodiments will occur to those skilled in the art. It is to be expressly understood that such modifications and alterations are within the scope and spirit of the present disclosure. Further, it is to be understood that the phraseology and terminology used herein is for the purposes of description and should not be regarded as limiting. The use of “including,” “comprising,” or “having” and variations thereof herein are meant to encompass the items listed thereafter and equivalents thereof, as well as, additional items. Further, it is to be understood that the claims is not necessarily limited to the specific features or steps Described herein. Rather, the specific features and steps are disclosed as embodiments of implementing the claimed systems and methods.

One aspect of the disclosure comprises any one or more of the aspects/embodiments as substantially disclosed herein.

Another aspect of the disclosure is any one or more of the aspects/embodiments as substantially disclosed herein optionally in combination with any one or more other aspects/embodiments as substantially disclosed herein.

One aspect of the present disclosure is a perovskite solar cell as described herein.

Another aspect of the disclosure is a method of making a perovskite solar cell according to any of the embodiments described herein.

Still another aspect of the present disclosure is a phosphonic acid molecule as described herein.

Another aspect of embodiments of the present disclosure is a display that comprises a functionalized aromatic phosphonic acid (FAPA) in a hole transport/extraction layer.

Other aspects of the present disclosure include methods of making phosphonic acid molecules according to any one or more of the embodiments described here.

It is another aspect of the present disclosure to provide one or more means adapted to perform any one or more of the above aspects/embodiments as substantially disclosed herein.

To provide additional background, context, and to further satisfy the written description requirements of 35 U.S.C. § 112, the following references are incorporated by reference herein in their entireties:
1. Park, J. et al., “Controlled growth of perovskite layers with volatile alkylammonium chlorides”, Nature 616, 724-730, doi: 10.1038/s41586-023-05825-y (2023).
2. Fei, C. et al., “Lead-chelating hole-transport layers for efficient and stable perovskite minimodules”, Science 380, 823-829, doi: 10.1126/science.ade9463 (2023).
3. Zhao, Y. et al, “Inactive (PbI2) 2RbCl stabilizes perovskite films for efficient solar cells”, Science 377, 531-534, doi: 10.1126/science.abp8873 (2022).
4. Grancini, G. et al., “One-Year stable perovskite solar cells by 2D/3D interface engineering”, Nat. Commun. 8, 15684, doi: 10.1038/ncomms15684 (2017).
5. Li, C. et al., “Rational design of Lewis base molecules for stable and efficient inverted perovskite solar cells”, Science 379, 690-694, doi: 10.1126/science.ade3970 (2023).
6. Zhao, X. et al., “Accelerated aging of all-inorganic, interface-stabilized perovskite solar cells,” Science 377, 307-310, doi: 10.1126/science.abn5679 (2022).
7. Wang, M. et al., “Ammonium cations with high pKa in perovskite solar cells for improved high-temperature photostability”, Nat. Energy, doi: 10.1038/s41560-023-01362-0 (2023).
8. Li, N. et al., “Liquid medium annealing for fabricating durable perovskite solar cells with improved reproducibility”, Science 373, 561-567, doi: 10.1126/science.abh3884 (2021).
9. Wang, M., Fei, C., Uddin, M. A. & Huang, J., “Influence of voids on the thermal and light stability of perovskite solar cells”, Sci. Adv. 8, eabo5977, doi: 10.1126/sciadv.abo5977 (2022).
10. Zheng, X. et al., “Co-deposition of hole-selective contact and absorber for improving the processability of perovskite solar cells”, Nat. Energy 8, 462-472, doi: 10.1038/s41560-023-01227-6 (2023).
11. Yin, J., Shi, X., Wang, L., Yan, H. & Chen, S., “High-Performance Inverted Perovskite Solar Devices Enabled by a Polyfullerene Electron Transporting Material”, Angew. Chem. Int. Ed. 61, e202210610, doi: https://doi.org/10.1002/anie.202210610 (2022).
12. Jiang, Q. et al., “Towards linking lab and field lifetimes of perovskite solar cells”, Nature, doi: 10.1038/s41586-023-06610-7 (2023).
13. Rahman, N. U. et al., “A promising europium-based down conversion material: organic-inorganic perovskite solar cells with high photovoltaic performance and UV-light stability”, J. Mater. Chem. A 7, 6467-6474, doi: 10.1039/C9TA00551J (2019).
14. Shi, L. et al., “Gas chromatography-mass spectrometry analyses of encapsulated stable perovskite solar cells”, Science 368, eaba2412, doi: 10.1126/science.aba2412 (2020).
15. Wang, T. et al., “Room temperature nondestructive encapsulation via self-crosslinked fluorosilicone polymer enables damp heat-stable sustainable perovskite solar cells”, Nat. Commun. 14, 1342, doi: 10.1038/s41467-023-36918-x (2023).
16. Xiao, X. et al., “Lead-adsorbing ionogel-based encapsulation for impact-resistant, stable, and lead-safe perovskite modules”, Sci. Adv. 7, eabi8249, doi: 10.1126/sciadv.abi8249 (2021).
17. Hussain, H. et al., “Structure of a model TiO2 photocatalytic interface”, Nat. Mater. 16, 461-466, doi: 10.1038/nmat4793 (2017).
18. Liu, R., Wang, L., Fan, Y., Li, Z. & Pang, S., “UV degradation of the interface between perovskites and the electron transport layer”, RSC Adv. 10, 11551-11556, doi: 10.1039/C9RA10960A (2020).
19. Li, W., Li, J., Niu, G. & Wang, L., “Effect of cesium chloride modification on the film morphology and UV-induced stability of planar perovskite solar cells”, J. Mater. Chem. A 4, 11688-11695, doi: 10.1039/C5TA09165A (2016).
20. Ji, J. et al., “Two-Stage Ultraviolet Degradation of Perovskite Solar Cells Induced by the Oxygen Vacancy-Ti4+ States”, iScience 23, 101013, doi: 10.1016/j.isci.2020.101013 (2020).
21. Petrović, M. et al., Limitations of a polymer-based hole transporting layer for application in planar inverted perovskite solar cells”, Nanoscale Advances 1, 3107-3118, doi: 10.1039/C9NA00246D (2019).
22. Park, J. H., Kwon, O. J., Kim, T.-H., Mun, J. & Park, Y. D., “Ultraviolet irradiation creates morphological order via conformational changes in polythiophene films”, Org. Electron. 62, 394-399, doi: https://doi.org/10.1016/j.orgel.2018.08.033 (2018).
23. Deng, Y. et al., “Defect compensation in formamidinium-caesium perovskites for highly efficient solar mini-modules with improved photostability”, Nat. Energy 6, 633-641, doi: 10.1038/s41560-021-00831-8 (2021).
24. Khenkin, M. V. et al., “Consensus statement for stability assessment and reporting for perovskite photovoltaics based on ISOS procedures”, Nat. Energy 5, 35-49, doi: 10.1038/s41560-019-0529-5 (2020).
25. Kerner, R. A. & Rand, B. P., “Electrochemical and Thermal Etching of Indium Tin Oxide by Solid-State Hybrid Organic-Inorganic Perovskites”, ACS Applied Energy Materials 2, 6097-6101, doi: 10.1021/acsaem.9b01356 (2019).
26. Ni, Z. et al., “Resolving spatial and energetic distributions of trap states in metal halide perovskite solar cells”, Science 367, 1352-1358, doi: 10.1126/science.aba0893 (2020).
27. Ni, Z. et al., “Evolution of defects during the degradation of metal halide perovskite solar cells under reverse bias and illumination”, Nat. Energy 7, 65-73, doi: 10.1038/s41560-021-00949-9 (2022).
28. Ye, J. et al., “Defect Passivation in Lead-Halide Perovskite Nanocrystals and Thin Films: Toward Efficient LEDs and Solar Cells”, Angew. Chem. Int. Ed. 60, 21636-21660, doi: https://doi.org/10.1002/anie.202102360 (2021).
29. Lin, Y. et al., “Excess charge-carrier induced instability of hybrid perovskites”, Nat. Commun. 9, 4981, doi: 10.1038/s41467-018-07438-w (2018).
30. Lin, Y. et al., “Self-Assembled Monolayer Enables Hole Transport Layer-Free Organic Solar Cells with 18% Efficiency and Improved Operational Stability”, ACS Energy Lett. 5, 2935-2944, doi: 10.1021/acsenergylett.0c01421 (2020).
31. Al-Ashouri, A. et al., “Conformal monolayer contacts with lossless interfaces for perovskite single junction and monolithic tandem solar cells”, Energy Environ. Sci. 12, 3356-3369, doi: 10.1039/C9EE02268F (2019).
32. Abdollahi Nejand, B. et al., “Scalable two-terminal all-perovskite tandem solar modules with a 19.1% efficiency”, Nat. Energy 7, 620-630, doi: 10.1038/s41560-022-01059-w (2022).
33. Lin, R. et al., “All-perovskite tandem solar cells with 3D/3D bilayer perovskite heterojunction”, Nature 620, 994-1000, doi: 10.1038/s41586-023-06278-z (2023).
34. Chen, S. et al., “Stabilizing perovskite-substrate interfaces for high-performance perovskite modules”, Science 373, 902-907, doi: 10.1126/science.abi6323 (2021).
35. PACT. PACT Perovskite PV Module Outdoor Test Protocol, <https://pvpact.sandia.gov/download/1305/> (2023).
36. Deng, Y. et al., “Tailoring solvent coordination for high-speed, room-temperature blading of perovskite photovoltaic films”, Sci. Adv. 5, eaax7537, doi: 10.1126/sciadv.aax7537 (2019).
37. Al-Ashouri, A., “Conformal monolayer contacts with lossless interfaces for perovskite single junction and monolithic tandem solar cells”, Energy Environ. Sci., 2019, 12, 3356-3369, DOI: 10.1039/C9EE02268F (2019) (available at: https://pubs.rsc.org/en/content/articlehtml/2019/ee/c9ee02268f).
38. Phung, N. et al., “Enhanced Self-Assembled Monolayer Surface Coverage by ALD NiO in p-i-n Perovskite Solar Cells”, ACS Applied Materials & Interfaces 2022 14 (1), 2166-2176, DOI: 10.1021/acsami.1c15860 (available at: https://pubs.acs.org/doi/pdf/10.1021/acsami.lc15860).
39. Lin, Y. et al., “18.4% Organic Solar Cells Using a High Ionization Energy Self-Assembled Monolayer as Hole-Extraction Interlayer”, ChemSusChem 2021, 14, 3569 (https://doi.org/10.1002/cssc.202100707) (available at https://chemistry-europe.onlinelibrary.wiley.com/doi/10.1002/cssc.202100707).
40. U.S. Patent Application Publication 2021/0234101A1.
41. U.S. Office of Energy Efficiency and Renewable Energy, Solar Energy Technologies Office, “Perovskite Solar Cells”, available at https://www.energy.gov/eere/solar/perovskite-solar-cells.

1. A chemical compound represented by any one of the structural formulas 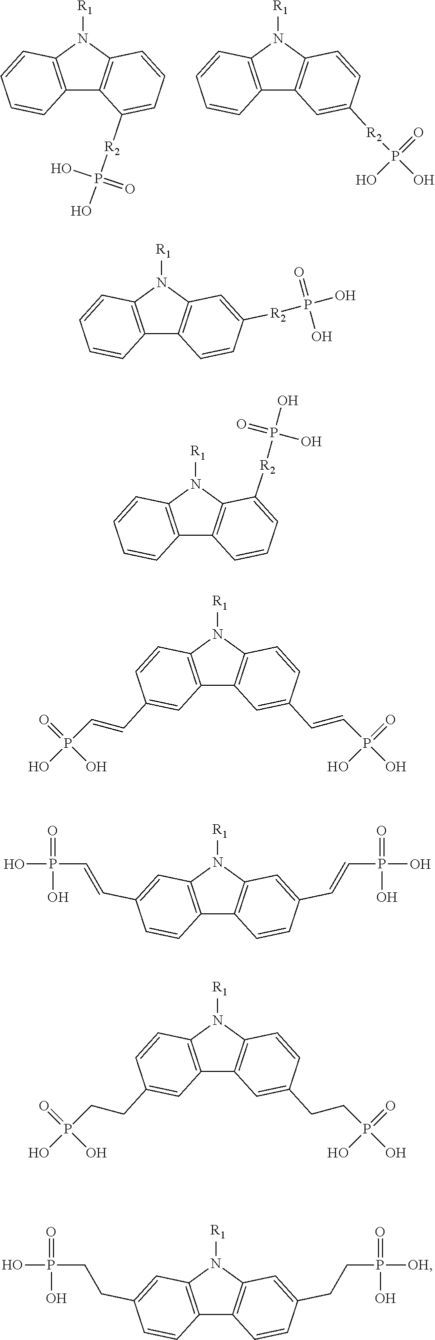
wherein R¹ or R is an alkyl group containing at least 1 and no more than 8 carbon atoms or a group of the form —CH₂CH₂ (OCH₂CH₂)ₙOCH₃, where n is an integer equal to at least 0 and no more than 5, and R² is ethyl or vinyl.

2. The chemical compound of claim 1, wherein R¹ is ethyl, R² is ethyl, and the chemical compound is (2-(9-ethyl-9H-carbazol-3-yl)ethyl)phosphonic acid.

3. The chemical compound of claim 1, wherein R¹ is ethyl, R² is vinyl, and the chemical compound is (E)-(2-(9-ethyl-9H-carbazol-3-yl)vinyl)phosphonic acid.

4. A perovskite film, comprising:
a transparent conducting oxide (TCO) substrate layer;
a perovskite layer; and
a hole transport layer comprising at least one chemical compound according to claim 1, disposed between and linking the TCO substrate and the perovskite layer.

5. The perovskite film of claim 4, wherein the at least one compound comprises (2-(9-ethyl-9H-carbazol-3-yl)ethyl)phosphonic acid, (E)-(2-(9-ethyl-9H-carbazol-3-yl)vinyl)phosphonic acid, (E)-(2-(9-ethyl-carbazol-2-yl)vinyl)phosphonic acid, (2-(9-ethyl-carbazol-2-yl)ethyl)phosphonic acid (EtCz2EPA), or a combination thereof.

6. The perovskite film of claim 4, wherein the hole transport layer further comprises poly[bis(4-phenyl)(2,4,6-trimethylphenyl)amine] and bathocuproine.

7. The perovskite film of claim 4, having a total thickness of between about 500 nm and about 1500 nm.

8. A solar cell, comprising the perovskite film of claim 4.

9. A display device, comprising the perovskite film of claim 4.

10. A method for making a chemical compound according to claim 1, wherein R² is vinyl, comprising:
reacting a carbazole starting material with vinyl phosphonic acid and a basic amine in the presence of a catalyst and a first solvent at a first temperature of between about 20° C. and about 120° C.,
wherein the carbazole starting material is selected from the group consisting of a 1-R⁴-9-R¹-9H-carbazole, a 2-R⁴-9-R¹-9H-carbazole, a 3-R⁴-9-R¹-9H-carbazole, a 4-R⁴-9-R¹-9H- carbazole, a 2-R⁴-7-R⁵-9-R¹-9H-carbazole, a 3-R⁴-6-R⁵-9-R¹-9H-carbazole, or a combination thereof, wherein each of R⁴ and R⁵ is a triflate group or a halogen atom.

11. The method of claim 10, wherein R⁴ is a bromine atom.

12. The method of claim 10, wherein the basic amine is N,N-dicyclohexylmethylamine.

13. The method of claim 10, wherein the catalyst is a palladium catalyst.

14. The method of claim 13, wherein the second catalyst comprises bis(tri-tert-butylphosphine)palladium(0).

15. The method of claim 10, wherein the second solvent comprises dioxane.

16. The method of claim 10, wherein the first temperature is about 80° C.

17. The method of claim 10, further comprising:
forming the carbazole starting material by reacting a 1-R⁴-9-R¹-9H-carbazole, a 2-R⁴-9-R¹-9H-carbazole, a 3-R⁴-9-R¹-9H-carbazole, a 4-R⁴-9-R¹-9H-carbazole, a 2-R⁴-7-R⁵-9- R¹-9H-carbazole, a 3-R⁴-6-R⁵-9-R¹-9H-carbazole, or a combination thereof with bromo-R¹, chloro-R¹, iodo-R¹, or a combination thereof, in the presence of a nucleophile and a second solvent at a second temperature of between about 20° C. and about 120° C.

18. The method of claim 17, wherein the nucleophile is potassium hydroxide.

19. The method of claim 17, wherein the second solvent comprises acetone.

20. The method of claim 17, wherein the second temperature is about 40° C.

21. A method for making 2-(9-R¹-9H-carbazol-3-yl)ethyl)phosphonic acid, comprising:
reacting (E)-(2-(9-R¹-9H-carbazol-3-yl)vinyl)phosphonic acid (EtCz3VPA) with a reducing agent in the presence of a catalyst and a solvent,
wherein R¹ is an alkyl group containing at least 1 and no more than 8 carbon atoms or a group of the form —CH₂CH₂ (OCH₂CH₂)ₙOCH₃, where n is an integer equal to at least 0 and no more than 5.

22. The method of claim 21, wherein the catalyst is a palladium on carbon (Pd/C) catalyst.

23. The method of claim 21, wherein the first solvent is selected from the group consisting of dioxane, ethanol, tetrahydrofuran, and combinations thereof.

24. The method of claim 21, wherein the reducing agent is triethylsilane.

25. A method for making a perovskite film, comprising:
(a) coating an indium tin oxide (ITO) substrate with a hole transport material (HTM) solution, the HTM solution comprising at least one chemical compound according to claim 1 as a solute;
(b) annealing the HTM solution-coated ITO substrate to remove a solvent of the HTM solution and form a device comprising an ITO substrate layer and a hole transport layer (HTL), the HTL comprising the EtCz3EPA and/or EtCz3VPA;
(c) coating the HTL with a perovskite precursor solution; and
(d) annealing the perovskite precursor solution-coated device to remove a solvent of the perovskite precursor solution and form a perovskite layer on a surface of the HTL opposite the ITO substrate, thereby forming the perovskite film.

26. The method of claim 25, wherein the at least one chemical compound comprises (2-(9-ethyl-9H-carbazol-3-yl)ethyl)phosphonic acid, (E)-(2-(9-ethyl-9H-carbazol-3-yl)vinyl)phosphonic acid, or a combination thereof.

27. The method of claim 25, wherein the HTL further comprises poly[bis(4-phenyl)(2,4,6-trimethylphenyl)amine] and bathocuproine.

28. The method of claim 25, wherein the thickness of the perovskite film is between about 500 nm and about 1500 nm.

29. A solar cell comprising a perovskite film made according to the method of claim 25.

30. A display device comprising the perovskite film of claim 25.
